(19) United States
(12) Patent Application Publication
(10) Pub. No.: US 2017/0057051 A1
(43) Pub. Date: Mar. 2, 2017

(54) EDDY CURRENT SENSOR

(71) Applicant: EBARA CORPORATION, Tokyo (JP)

(72) Inventor: Akira NAKAMURA, Tokyo (JP)

(21) Appl. No.: 15/253,671

(22) Filed: Aug. 31, 2016

(30) Foreign Application Priority Data
Sep. 1, 2015 (JP) 172007-2015
Sep. 16, 2015 (JP) 183003-2015

(51) Int. Cl. B24B 49/10; H01L 21/67; H01L 21/66; G01B 7/06; B24B 37/013

(52) U.S. Cl. CPC B24B 49/105; G01B 7/10; B24B 37/013; H01L 22/26; H01L 21/67092

(57) ABSTRACT

An eddy current sensor 1-50 arranged in the vicinity of a substrate includes a core part 1-60 and a coil part 1-61. The core part 1-60 includes a common part 1-65, and four cantilever parts 1-66 to 69 connected to the common part 1-65. Ends of a first cantilever part 1-66 and a second cantilever part 1-67 are close and adjacent to each other. Ends of a third cantilever part 1-69 and a fourth cantilever part 1-68 are close and adjacent to each other. At the common part 1-65, an excitation coil is arranged. A first detection coil 1-631 is arranged at the first cantilever part 1-66 and a second detection coil 1-632 is arranged at the second cantilever part 1-67. A first dummy coil 1-642 is arranged at the third cantilever part 1-69, and a second dummy coil 1-641 is arranged at the fourth cantilever part 1-68.

### CROSS-REFERENCE TO RELATED APPLICATION

This application claims priority to Japanese Patent Applications No. 172007-2015 filed on Sep. 1, 2015 and 183003-2015 filed on Sep. 16, 2015. The entire disclosure of Japanese Patent Applications No. 172007-2015 filed on Sep. 1, 2015 and 183003-2015 filed on Sep. 16, 2015 including specification, claims, drawings and summary are incorporated herein by reference in its entirety.

### TECHNICAL FIELD

The present invention relates to an eddy current sensor suitable for detecting a conductive film such as a metal film formed on a surface of a substrate such as a semiconductor wafer.

### BACKGROUND ART

In recent years, wiring of a circuit is micronized as high integration of a semiconductor device advances, and an inter-wiring distance tends to be narrower. Therefore, it is needed to flatten a surface of a semiconductor wafer which is a polishing object, and polishing is performed by a polishing device as a means of the flattening method.

A polishing device includes a polishing table for holding a polishing pad for polishing a polishing object, and a top ring for holding the polishing object and pressurizing it to the polishing pad. The polishing table and the top ring are each rotationally driven by a drive unit (a motor, for example). By making liquid (slurry) containing a polishing agent flow onto the polishing pad and pressing the polishing object held by the top ring there, the polishing object is polished.

In the polishing device, when the polishing object is insufficiently polished, circuits are not insulated, causing a risk of a short circuit, and when the polishing object is overpolished, problems in that a resistance value rises due to reduction of a cross section of wiring or the wiring itself is completely removed and the circuit itself is not formed or the like arise. Therefore, in the polishing device, it is demanded to detect an optimum polishing end point.

Such techniques are described in Japanese Patent Laid-Open No. 2012-135865 and Japanese Patent Laid-Open No. 2013-58762. In these techniques, a solenoid type or spiral type coil is used.

In recent years, in order to reduce a defective article rate near an edge of a semiconductor wafer, there is a demand to measure a film thickness closer to the edge of the semiconductor wafer and control the film thickness by in-situ closed loop control.

In addition, for the top ring, there is the one of an airbag head type utilizing an air pressure or the like. An airbag head includes a plurality of concentric air bags. There is a demand to improve a resolution of ruggedness on a surface of the semiconductor wafer by an eddy current sensor and measure a film thickness of a narrower range in order to control the film thickness by the airbag of a narrow width.

However, in the solenoid type or spiral type coil, it is difficult to narrow a magnetic flux, and measurement of a narrow range is limited.

Japanese Patent Laid-Open No. 2009-204342 describes that dimensional resonance of electromagnetic waves is generated inside a magnetic core of an eddy current sensor and a magnetic field is intensively generated in a range smaller than a cross section of the magnetic core. Since the magnetic field is given to a metal film, a spatial resolution smaller than the cross section of the magnetic core of the eddy current sensor can be obtained. However, when the dimensional resonance of electromagnetic waves is used, though the magnetic flux becomes narrow, there is a disadvantage that the magnetic flux becomes weak (the magnetic field becomes weak).

In addition, for the dimensional resonance, Japanese Patent Laid-Open No. 2009-204342 describes that in the case of using Mn—Zn ferrite or the like that a dielectric property becomes remarkable in addition to a magnetic property for a magnetic core material of an eddy current sensor, for example, a phenomenon in that an electromagnetic wave inside the magnetic core becomes a stationary wave under high frequency excitation of a MHz band is known, and it is referred to as dimensional resonance. A magnetic flux is concentrated in a crest section of the stationary wave, so that the magnetic field generation area (magnetic flux cross section) is made smaller than a magnetic path cross section of the magnetic core and that the magnetic flux is applied to a sample.”

Therefore, an object in one form of the present invention is to measure a film thickness of a narrower range and to improve polishing flatness of a wafer.

### SUMMARY OF INVENTION

According to a first form of a polishing device of the present invention, an eddy current sensor is arranged in a vicinity of a substrate where a conductive film is formed, the eddy current sensor includes a core part and a coil part, the core part includes a common part and four cantilever parts connected to an end of the common part, and a first cantilever part and a second cantilever part are arranged on an opposite side of a third cantilever part and a fourth cantilever part with respect to the common part. The first cantilever part and the third cantilever part are arranged at one end of the common part, and the second cantilever part and the fourth cantilever part are arranged at the other end of the common part. The coil part includes: an excitation coil that is arranged in the common part and is capable of forming an eddy current at the conductive film; a detection coil that is arranged in at least one of the first cantilever part and the second cantilever part, and is capable of detecting the eddy current formed at the conductive film; and a dummy coil that is arranged in at least one of the third cantilever part and the fourth cantilever part. Ends of the first cantilever part and the second cantilever part far from parts where the first cantilever part and the second cantilever part are connected with the common part are close and adjacent to each other, and ends of the third cantilever part and the fourth cantilever part far from parts where the third cantilever part and the fourth cantilever part are connected with the common part are close and adjacent to each other.

According to a second form of the present invention, an eddy current sensor is arranged in a vicinity of a substrate where a conductive film is formed, and the eddy current sensor includes a sensor part and a dummy part arranged in a vicinity of the sensor part. The sensor part includes a sensor core part and a sensor coil part, the sensor core part includes a sensor common part and a first cantilever part and a second cantilever part connected to the sensor common part, and the first cantilever part and the second cantilever part are arranged facing each other. The dummy part includes a dummy core part and a dummy coil part, the dummy core part includes a dummy common part and a fourth cantilever part and a third cantilever part connected to the dummy common part, and the fourth cantilever part and the third cantilever part are arranged facing each other. The sensor coil part includes a sensor excitation coil that is arranged in the sensor common part and is capable of forming an eddy current at the conductive film, and a detection coil that is arranged in at least one of the first cantilever part and the second cantilever part, and is capable of detecting the eddy current formed at the conductive film. The dummy coil part includes a dummy excitation coil that is arranged in the dummy common part, and a dummy coil that is arranged in at least one of the third cantilever part and the fourth cantilever part. Ends of the first cantilever part and the second cantilever part far from parts where the first cantilever part and the second cantilever part are connected with the sensor common part are close and adjacent to each other, ends of the third cantilever part and the fourth cantilever part far from parts where the third cantilever part and the fourth cantilever part are connected with the dummy common part are close and adjacent to each other, and the sensor part and the dummy part are arranged in an order of the sensor part and the dummy part from a position near the substrate to a position far from the substrate.

According to a third form of the polishing device of the present invention, an eddy current sensor is arranged in a vicinity of a substrate where a conductive film is formed, and the eddy current sensor includes: a pot core which is a magnetic body including a bottom surface part, a magnetic core part provided on a center of the bottom surface part, and a peripheral wall part provided around the bottom surface part; an excitation coil that is arranged at the magnetic core part and forms an eddy current at the conductive film; and a detection coil that is arranged at the magnetic core part, and detects the eddy current formed at the conductive film. Relative permittivity of the magnetic body is 5 to 15, relative permeability is 1 to 300, an outside dimension of the magnetic core part is 50 mm or smaller, and electric signals of a frequency of 2 to 30 MHz are applied to the excitation coil. Here, the outside dimension of the magnetic core part is the maximum dimension of a cross section of the core part vertical to a magnetic field applied to the magnetic core part by the excitation coil.

According to a fourth form of the present invention, an eddy current sensor is arranged in a vicinity of a substrate where a conductive film is formed, the eddy current sensor includes a first pot core and a second pot core arranged in the vicinity of the first pot core, and the first pot core and the second pot core each include a bottom surface part, a magnetic core part provided on a center of the bottom surface part, and a peripheral wall part provided around the bottom surface part. The eddy current sensor includes: a first excitation coil that is arranged in the magnetic core part of the first pot core and forms an eddy current at the conductive film; a detection coil that is arranged at the magnetic core part of the first pot core, and detects the eddy current formed at the conductive film; a second excitation coil that is arranged at the magnetic core part of the second pot core; and a dummy coil that is arranged at the magnetic core part of the second pot core. An axial direction of the magnetic core part of the first pot core and an axial direction of the magnetic core part of the second pot core coincide, and the first pot core and the second pot core are arranged in an order of the first pot core and the second pot core from a position near the substrate to a position far from the substrate.

### BRIEF DESCRIPTION OF DRAWINGS

FIG. 1 is a schematic diagram illustrating an entire configuration of a polishing device in one embodiment relating to the present invention;

FIG. 2 is a plan view illustrating a relationship of a polishing table, an eddy current sensor and a semiconductor wafer;

FIGS. 3A and 3B are diagrams illustrating a configuration of the eddy current sensor, wherein FIG. 3A is a block diagram illustrating the configuration of the eddy current sensor and FIG. 3B is an equivalent circuit diagram of the eddy current sensor;

FIG. 4 is diagrams illustrating a conventional eddy current sensor and the eddy current sensor of one embodiment of the present invention in comparison, wherein FIG. 4(a) is a schematic diagram illustrating a configuration example of the conventional eddy current sensor, and FIG. 4(b) is a schematic diagram illustrating a configuration example of the eddy current sensor of one embodiment of the present invention;

FIG. 5 is an enlarged view of an eddy current sensor 1-50 in FIG. 4(b);

FIG. 6 is a schematic diagram illustrating an example of arranging an outer peripheral part 1-210 which is a cylindrical member formed of a metallic material around the eddy current sensor 1-50;

FIG. 7 is a diagram illustrating four grooves 1-226 extending in an axial direction of the eddy current sensor;

FIG. 8 is a diagram illustrating another configuration of the eddy current sensor;

FIGS. 9A, 9B and 9C are schematic diagrams illustrating a connection example of individual coils in the eddy current sensor;

FIG. 10 is a block diagram illustrating a synchronization detection circuit of the eddy current sensor;

FIG. 11 is a block diagram illustrating a method of controlling a film thickness;

FIG. 12 is a schematic drawing illustrating a track on which the eddy current sensor performs a scan on a semiconductor wafer;

FIG. 13 is a schematic drawing illustrating a track on which the eddy current sensor performs a scan on a semiconductor wafer;

FIG. 14 is a flowchart illustrating one example of an operation of pressure control performed during polishing;

FIG. 15 is a schematic diagram illustrating an entire configuration of a polishing device in one embodiment relating to the present invention;

FIG. 16 is a plan view illustrating a relationship of a polishing table, an eddy current sensor and a semiconductor wafer;

FIGS. 17A and 17B are diagrams illustrating a configuration of the eddy current sensor, wherein FIG. 17A is a block diagram illustrating the configuration of the eddy current sensor and FIG. 17B is an equivalent circuit diagram of the eddy current sensor;

FIG. 18 is diagrams illustrating a conventional eddy current sensor and the eddy current sensor of one embodiment of the present invention in comparison, wherein FIG. 18(a) is a schematic diagram illustrating a configuration example of the conventional eddy current sensor, and FIG. 18(b) is a schematic diagram illustrating a configuration example of the eddy current sensor of one embodiment of the present invention;

FIG. 19 is a diagram illustrating a detailed shape of a pot core 2-60;

FIG. 20 is a schematic diagram illustrating an example of arranging an outer peripheral part 2-210 which is a cylindrical member formed of a metallic material around an eddy current sensor 2-50;

FIGS. 21A and 21B are diagrams illustrating four grooves 2-226 extending in an axial direction of a magnetic core part 2-61b;

FIGS. 22A and 22B are diagrams illustrating another configuration of the eddy current sensor;

FIGS. 23A, 23B and 23C are schematic diagrams illustrating a connection example of individual coils in the eddy current sensor;

FIG. 24 is a block diagram illustrating a synchronization detection circuit of the eddy current sensor;

FIG. 25 is a block diagram illustrating a method of controlling a film thickness;

FIG. 26 is a schematic drawing illustrating a track that the eddy current sensor performs a scan on a semiconductor wafer;

FIG. 27 is a schematic drawing illustrating a track that the eddy current sensor performs a scan on a semiconductor wafer; and

FIG. 28 is a flowchart illustrating one example of an operation of pressure control performed during polishing.

### DESCRIPTION OF EMBODIMENTS

Hereinafter, embodiments of a polishing device relating to the present invention will be described in detail with reference to the attached drawings. Note that, in the attached drawings, the same signs are attached to the same or corresponding components and redundant descriptions will be omitted.

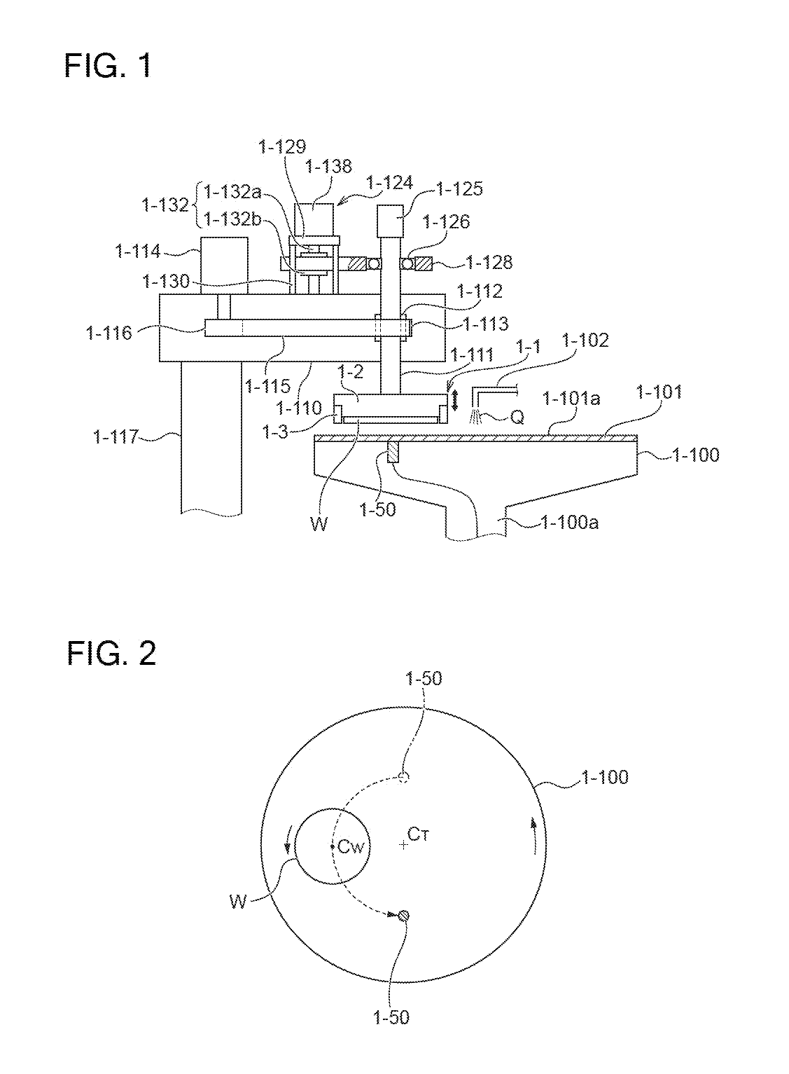

FIG. 1 is a schematic diagram illustrating an entire configuration of a polishing device in one embodiment relating to the present invention. As illustrated in FIG. 1, the polishing device includes a polishing table 1-100 and a top ring (holding part) 1-1 that holds a substrate such as a semiconductor wafer which is a polishing object and pressurizes it to a polishing surface on the polishing table.

The polishing table 1-100 is connected to a motor (not shown in the figure) which is a drive part arranged at the lower part through a table shaft 1-100a, and is rotatable around the table shaft 1-100a. A polishing pad 1-101 is stuck to an upper surface of the polishing table 1-100, and a surface 1-101a of the polishing pad 1-101 configures a polishing surface that polishes a semiconductor wafer W. A polishing liquid supply nozzle 1-102 is installed above the polishing table 1-100, and a polishing liquid Q is supplied onto the polishing pad 1-101 on the polishing table 1-100 by the polishing liquid supply nozzle 1-102. As illustrated in FIG. 1, an eddy current sensor 1-50 is embedded inside the polishing table 1-100.

The top ring 1-1 is basically configured from a top ring main body 1-2 that pressurizes the semiconductor wafer W to the surface 1-101a, and a retainer ring 1-3 that holds an outer peripheral edge of the semiconductor wafer W and prevents the semiconductor wafer W from jumping out of the top ring.

The top ring 1-1 is connected to a top ring shaft 1-111, and the top ring shaft 1-111 is vertically moved with respect to a top ring head 1-110 by a vertical movement mechanism 1-124. By the vertical movement of the top ring shaft 1-111, the entire top ring 1-1 is elevated and lowered and positioned with respect to the top ring head 1-110. Note that a rotary joint 1-125 is attached to an upper end of the top ring shaft 1-111.

The vertical movement mechanism 1-124 that vertically moves the top ring shaft 1-111 and the top ring 1-1 includes a bridge 1-128 that rotatably supports the top ring shaft 1-111 through a bearing 1-126, a ball screw 1-132 attached to the bridge 1-128, a support base 1-129 supported by a column 1-130, and an AC servo motor 1-138 provided on the support base 1-129. The support base 1-129 that supports the servo motor 1-138 is fixed through the column 1-130 to the top ring head 1-110.

The ball screw 1-132 includes a screw shaft 1-132a connected to the servo motor 1-138, and a nut 1-132b to which the screw shaft 1-132a is screwed. The top ring shaft 1-111 is vertically moved integrally with the bridge 1-128. Therefore, when the servo motor 1-138 is driven, the bridge 1-128 is vertically moved through the ball screw 1-132, and thus the top ring shaft 1-111 and the top ring 1-1 are vertically moved.

In addition, the top ring shaft 1-111 is connected to a rotary cylinder 1-112 through a key (not shown in the figure). The rotary cylinder 1-112 includes a timing pulley 1-113 on the outer peripheral part. A motor 1-114 for the top ring is fixed to the top ring head 1-110, and the timing pulley 1-113 is connected to a timing pulley 1-116 provided on the motor 1-114 for the top ring through a timing belt 1-115. Therefore, by rotationally driving the motor 1-114 for the top ring, the rotary cylinder 1-112 and the top ring shaft 1-111 are integrally rotated through the timing pulley 1-116, the timing belt 1-115 and the timing pulley 1-113, and the top ring 1-1 is rotated. Note that the top ring head 1-110 is supported by a top ring head shaft 1-117 rotatably supported by a frame (not shown in the figure).

In the polishing device configured as illustrated in FIG. 1, the top ring 1-1 can hold a substrate such as the semiconductor wafer W on the lower surface. The top ring head 1-110 is configured so as to turn around the top ring head shaft 1-117, and the top ring 1-1 holding the semiconductor wafer W on the lower surface is moved from a position to receive the semiconductor wafer W to an upper part of the polishing table 1-100 by turning of the top ring head 1-110. Then, the top ring 1-1 is lowered and the semiconductor wafer W is pressurized to the surface (polishing surface) 1-101a of the polishing pad 1-101. At the time, the top ring 1-1 and the polishing table 1-100 are rotated respectively, and the polishing liquid is supplied from the polishing liquid supply nozzle 1-102 provided above the polishing table 1-100 onto the polishing pad 1-101. In such a manner, the semiconductor wafer W is brought into slidable contact with the polishing surface 1-101a of the polishing pad 1-101, and the surface of the semiconductor wafer W is polished.

FIG. 2 is a plan view illustrating a relationship of the polishing table 1-100, the eddy current sensor 1-50 and the semiconductor wafer W. As illustrated in FIG. 2, the eddy current sensor 1-50 is installed at a position to pass through a center Cw of the semiconductor wafer W during polishing which is held by the top ring 1-1. A sign C_{T} is a rotation center of the polishing table 1-100. For example, the eddy current sensor 1-50 can detect a metal film (conductive film) such as a Cu layer of the semiconductor wafer W continuously on a passing track (scanning line), while passing through a lower part of the semiconductor wafer W.

Next, the eddy current sensor 1-50 provided in the polishing device relating to one embodiment of the present invention will be described more in detail using the attached drawings.

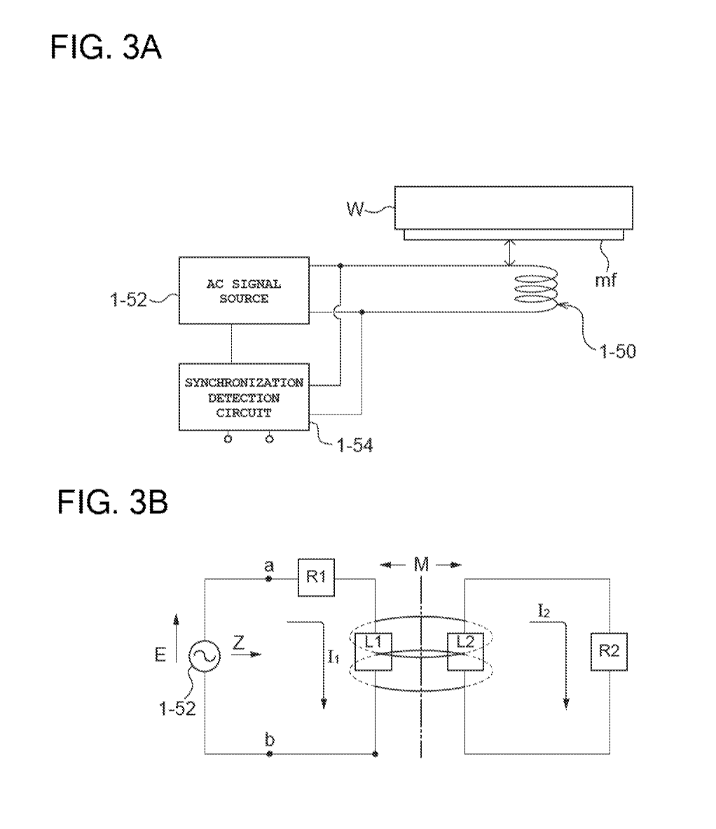

FIGS. 3A and 3B are diagrams illustrating a configuration of the eddy current sensor 1-50, FIG. 3A is a block diagram illustrating the configuration of the eddy current sensor 1-50, and FIG. 3B is an equivalent circuit diagram of the eddy current sensor 1-50.

As illustrated in FIG. 3A, the eddy current sensor 1-50 is arranged in the vicinity of a metal film (or conductive film) mf of a detection object, and an AC signal source 1-52 is connected to the coil. Here, the metal film (or conductive film) mf of the detection object is a thin film of Cu, Al, Au, W or the like formed on the semiconductor wafer W, for example. The eddy current sensor 1-50 is arranged in the vicinity of about 1.0 to 4.0 mm, for example, with respect to the metal film (or conductive film) of the detection object.

As the eddy current sensor, there are a frequency type in which an oscillation frequency is changed by generation of an eddy current in a metal film (or conductive film) 1-mf and the metal film (or conductive film) is detected from the frequency change, and an impedance type in which an impedance is changed and the metal film (or conductive film) is detected from the impedance change. That is, in the frequency type, in an equivalent circuit illustrated in FIG. 3B, by the change of an eddy current I₂, an impedance Z is changed, and when the oscillation frequency of the signal source (variable frequency oscillator) 1-52 changes, the change of the oscillation frequency is detected in a detection circuit 1-54, and the change of the metal film (or conductive film) can be detected. In the impedance type, in the equivalent circuit illustrated in FIG. 3B, by the change of the eddy current I₂, an impedance 1-Z is changed, and when the impedance in the view from the signal source (fixed frequency oscillator) 1-52 changes, the change of the impedance Z is detected in the detection circuit 1-54, and the change of the metal film (or conductive film) can be detected.

In the eddy current sensor of the impedance type, signal outputs X, Y, a phase, and a combined impedance Z are taken out as described later. From a frequency F or impedances X, Y or the like, measurement information of a metal film (or conductive film) Cu, Al, Au, W is obtained. The eddy current sensor 1-50 can be incorporated at a position near the surface inside the polishing table 1-100 as illustrated in FIG. 1, is positioned to face the semiconductor wafer of the polishing object through the polishing pad, and can detect the change of the metal film (or conductive film) from the eddy current flowing in the metal film (or conductive film) on the semiconductor wafer.

For a frequency of the eddy current sensor, a single radio wave, a mixed radio wave, an AM modulated radio wave, an FM modulated radio wave, sweep output of a function generator or a plurality of oscillation frequency sources can be used, and it is preferable to select an oscillation frequency or a modulation system with excellent sensitivity matched with a film kind of the metal film.

Hereinafter, the eddy current sensor of the impedance type will be specifically described. The AC signal source 1-52 is an oscillator of a fixed frequency of about 2 to 30 MHz, and a crystal oscillator is used, for example. Then, with an AC voltage supplied by the AC signal source 1-52, a current I₁ flows to the eddy current sensor 1-50. Since the current flows to the eddy current sensor 1-50 arranged in the vicinity of the metal film (or conductive film) mf, the magnetic flux is interlinked with the metal film (or conductive film) mf, thereby forming a mutual inductance M between them, and the eddy current I₂ flows in the metal film (or conductive film) mf. Here, reference character R1 denotes a primary side equivalent resistor including the eddy current sensor, and reference character L₁ denotes a primary side self-inductance similarly including the eddy current sensor. On the side of the metal film (or conductive film) mf, reference character R2 is an equivalent resistor corresponding to eddy current loss, and reference character L₂ is the self-inductance thereof. The impedance Z viewing an eddy current sensor side from terminals a and b of the AC signal source 1-52 changes depending on the size of the eddy current loss formed in the metal film (or conductive film) mf.

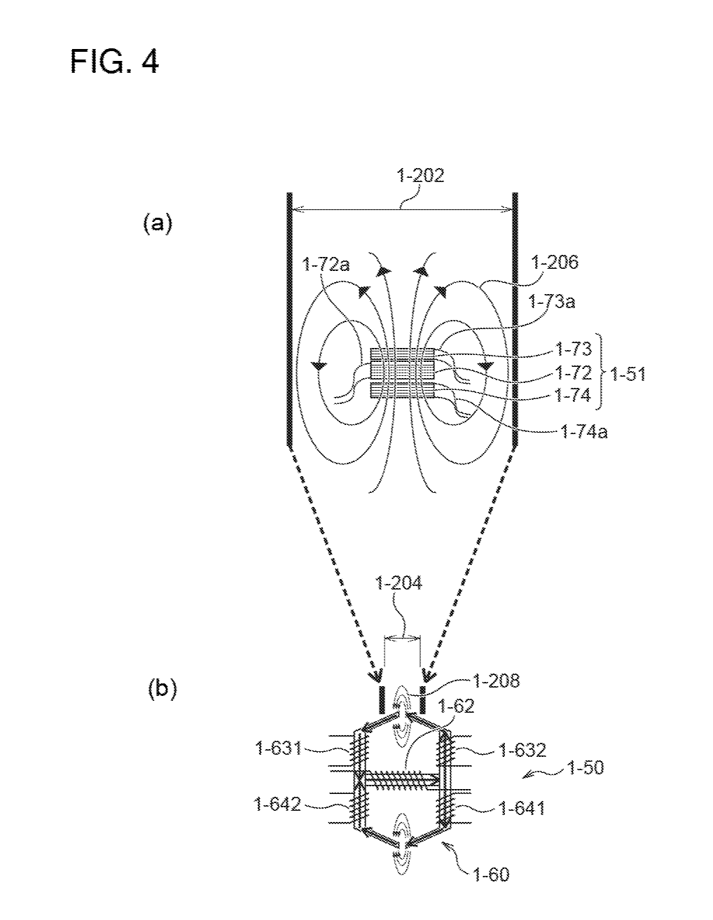

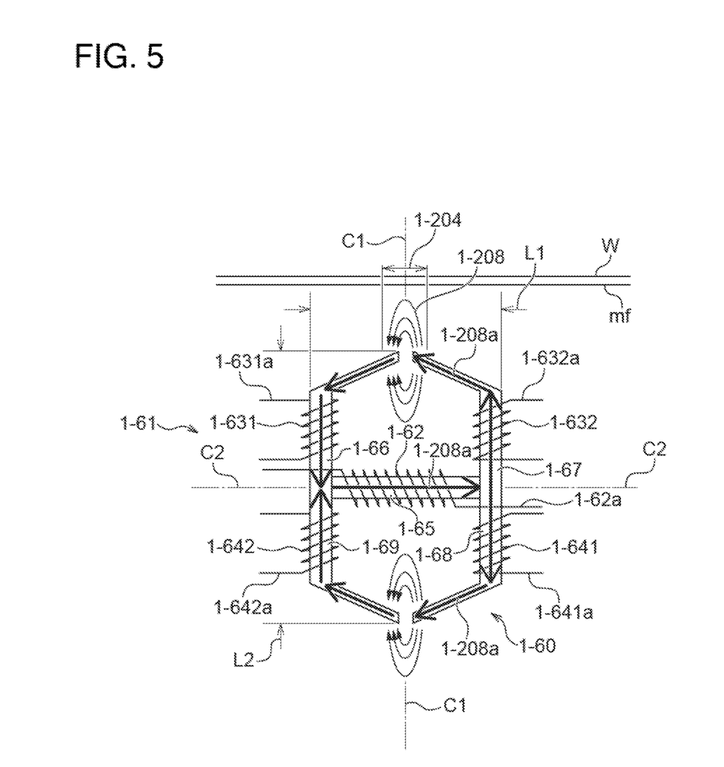

FIG. 4 is diagrams illustrating a conventional eddy current sensor and the eddy current sensor of one embodiment of the present invention in comparison. FIG. 4(a) is a schematic diagram illustrating a configuration example of the conventional eddy current sensor, and FIG. 4(b) is a schematic diagram illustrating a configuration example of the eddy current sensor 1-50 of one embodiment of the present invention. In FIGS. 4(a) and 4(b), spreads of the respective magnetic fluxes when the conventional eddy current sensor and the eddy current sensor of one embodiment of the present invention are of the equal size are illustrated in comparison. As is clear from FIG. 4, it is understood that the magnetic flux is concentrated and the spread of the magnetic flux is narrow in the eddy current sensor 1-50 of one embodiment of the present invention in contrast with the conventional eddy current sensor. FIG. 5 illustrates an enlarged view of the eddy current sensor 1-50 in FIG. 4(b).

As illustrated in FIG. 4(a), for a conventional eddy current sensor 1-51, a coil 1-72 for forming an eddy current at the metal film (or conductive film) and coils 1-73 and 74 for detecting the eddy current of the metal film (or conductive film) are separated, and it is configured by the three coils 1-72, 73 and 74 wound around a core (not shown in the figure). Here, the coil 1-72 at the center is an excitation coil connected to the AC signal source 1-52. The excitation coil 1-72 is supplied with an AC voltage from the AC signal source 1-52 and forms a magnetic field, and the magnetic field forms the eddy current at the metal film (or conductive film) mf on the semiconductor wafer (substrate) W arranged in the vicinity of the eddy current sensor 1-51. On the metal film (or conductive film) side of the core, the detection coil 1-73 is arranged, and detects the magnetic field generated by the eddy current formed at the metal film (or conductive film). On an opposite side of the detection coil 1-73 across the excitation coil 1-72, the dummy (balance) coil 1-74 is arranged.

In contrast, the eddy current sensor 1-50 of one embodiment of the present invention arranged in the vicinity of the substrate where the conductive film is formed is configured by a core part 1-60 and five coils 1-62, 631, 632, 641 and 642, as illustrated in FIG. 4(b) and FIG. 5. The core part 1-60 which is a magnetic body includes a common part 1-65, and four cantilever parts 1-66 to 69 connected to an end of the common part 1-65.

A first cantilever part 1-66 and a second cantilever part 1-67 are arranged facing each other, and a third cantilever part 1-69 and a fourth cantilever part 1-68 are arranged facing each other, and the first cantilever part 1-66, the second cantilever part 1-67, the fourth cantilever part 1-68 and the third cantilever part 1-69 are arranged in a planar view in the order clockwise with respect to the common part 1-65. The first cantilever part 1-66 and the third cantilever part 1-69 are arranged at one end of the common part 1-65, and the second cantilever part 1-67 and the fourth cantilever part 1-68 are arranged at the other end of the common part 1-65.

The first cantilever part 1-66 and the second cantilever part 1-67 are arranged on a side nearer to the substrate W than the common part 1-65, and the third cantilever part 1-69 and the fourth cantilever part 1-68 are arranged on a side farther from the substrate W than the common part 1-65. That is, the first cantilever part 1-66 and the second cantilever part 1-67 are arranged on the opposite side of the third cantilever part 1-69 and the fourth cantilever part 1-68 with respect to the common part 1-65.

Ends of the first cantilever part 1-66 and the second cantilever part 1-67 far from parts where the first cantilever part 1-66 and the second cantilever part are connected with the common part 1-65 are close and adjacent to each other. Similarly, ends of the third cantilever part 1-69 and the fourth cantilever part 1-68 far from parts where the third cantilever part 1-69 and the fourth cantilever part 1-68 are connected with the common part 1-65 are close and adjacent to each other.

The ends of the first cantilever part 1-66 and the second cantilever part 1-67 are close and adjacent to each other so that the core part 1-60 is a tapered shape in a direction away from parts where the first cantilever part 1-66 and the second cantilever part 1-67 are connected with the common part 1-65. Similarly, the ends of the third cantilever part 1-69 and the fourth cantilever part 1-68 are close and adjacent to each other so that the core part 1-60 is a tapered shape in a direction away from parts where the third cantilever part 1-69 and the fourth cantilever part 1-68 are connected with the common part 1-65.

The four cantilever parts 1-66 to 69 have two orthogonal center lines c1 and c2. The first cantilever part 1-66 and the second cantilever part 1-67 are in a symmetrical shape with respect to the one center line c1 in the planar view, and the third cantilever part 1-69 and the fourth cantilever part 1-68 are in a symmetrical shape with respect to the one center line c1 in the planar view. The first cantilever part 1-66 and the third cantilever part 1-69 are in a symmetrical shape with respect to the other center line c2, and the second cantilever part 1-67 and the fourth cantilever part 1-68 are in a symmetrical shape with respect to the other center line c2.

In the present embodiment, the four cantilever parts 1-66 to 69 are in the symmetrical shape, however, in the present invention, they are not limited to a strictly symmetrical shape. For the four cantilever parts 1-66 to 69, a slight shape difference or size difference is not a problem in terms of a performance. In addition, the first cantilever part 1-66 and the third cantilever part 1-69 can be in a twisted shape with respect to the common part 1-65. Even in this case, the first cantilever part 1-66 and the second cantilever part 1-67 are in the symmetrical shape with respect to the center line c1 in the planar view.

The common part 1-65 and the four cantilever parts 1-66 to 69 are planar, that is, each shape on a cross section vertical to a longitudinal direction of each of them is rectangular in the present embodiment. The common part 1-65 and the four cantilever parts 1-66 to 69 are not limited to the planar shape, and an arbitrary shape is possible. For example, it may be a rod shape, that is, the cross-sectional shape may be circular.

Of the five coils 1-62, 631, 632, 641 and 642, the coil 1-62 arranged at the common part 1-65 is an excitation coil connected to the AC signal source 1-52. The excitation coil 1-62 forms the eddy current at the metal film (or conductive film) mf on the semiconductor wafer W arranged in the vicinity by a magnetic field formed by a voltage supplied from the AC signal source 1-52. To the excitation coil 1-62, for example, electric signals of a frequency being 2 MHz or higher are applied. For the frequency applied to the excitation coil 1-62, an arbitrary frequency can be applied.

The first detection coil 1-631 arranged at the first cantilever part 1-66, and the second detection coil 1-632 arranged at the second cantilever part 1-67 both detect the eddy current formed at the conductive film. The first dummy coil 1-642 is arranged at the third cantilever part 1-69, and the second dummy coil 1-641 is arranged at the fourth cantilever part 1-68.

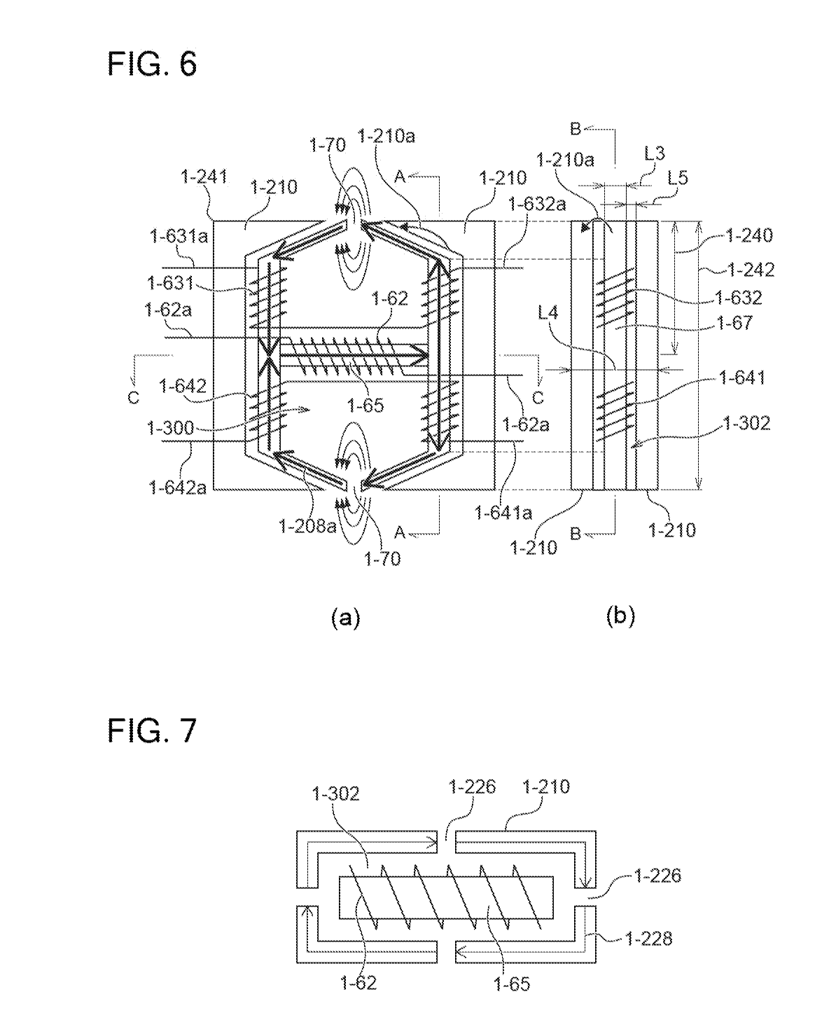

The first detection coil 1-631 and the second detection coil 1-632 can detect the eddy current independently, however, the first detection coil 1-631 and the second detection coil 1-632 may be connected in series to detect the eddy current. In the case of connecting the first detection coil 1-631 and the second detection coil 1-632 in series, the first dummy coil 1-642 and the second dummy coil 1-641 are also connected in series. In FIG. 6 to be described later, such connections are performed.

When the first detection coil 1-631 and the second detection coil 1-632 detect the eddy current independently, the detection coils 1-631 and 632 are more affected by the film thickness of the metal film (or conductive film) mf in an area near the detection coils 1-631 and 632. When this phenomenon is utilized, a narrower area can be detected in the case of detecting the eddy current using the first detection coil 1-631 and the second detection coil 1-632 independently, compared to the case of connecting the first detection coil 1-631 and the second detection coil 1-632 in series. On the other hand, in the case of connecting the first detection coil 1-631 and the second detection coil 1-632 in series, there is an advantage that output becomes larger, compared to the case of detecting the eddy current using the first detection coil 1-631 and the second detection coil 1-632 independently.

In FIG. 4(b) and FIG. 5, the four coils 1-631, 632, 641 and 642 are arranged at the four cantilever parts 1-66 to 69 of the core part 1-60. However, the two coils 1-631 and 642 may be arranged at the two cantilever parts 1-66 and 69 (or the two coils 1-632 and 641 may be arranged at the two cantilever parts 1-67 and 68) and coils may not be arranged at the other two cantilever parts 1-67 and 68 (66 and 69). The eddy current in the narrow area can be detected also in this case.

From the excitation coil 1-62 and the coils 1-631, 632, 641 and 642, lead wires 1-62a, 631a, 632a, 641a and 642a for connection with the outside are put out respectively. A range 1-202 in FIG. 4(a) illustrates the spread of a magnetic flux 1-206 of the conventional eddy current sensor, and a range 1-204 in FIG. 4(b) illustrates the spread of a magnetic flux 1-208 of the eddy current sensor of one embodiment of the present invention. In FIG. 4(b), a magnetic field leaking out from a small gap (a cut of magnetic bodies) between ends of the first cantilever part 1-66 and the second cantilever part 1-67 which are the magnetic bodies is used for forming the eddy current at the metal film (or conductive film) mf on the semiconductor wafer W. Therefore, the spread of the magnetic flux 1-208 is limited, the magnetic flux 1-208 becomes narrow, and a small spot diameter of the magnetic flux can be formed. FIG. 5 illustrates one example of a direction of the magnetic flux inside the common part 1-65 and the four cantilever parts 1-66 to 69 by an arrow 208a.

In the case of FIG. 4(a) of the conventional technique, since the magnetic body exists only in a core of a coil, the magnetic flux 1-206 is not converged outside the coil. Therefore, the magnetic flux 1-206 spreads and the range 1-202 of the magnetic flux 1-206 becomes wide. In the present invention, the magnetic body configures a closed loop, and the magnetic body is provided with a small gap so that the magnetic body does not exist only in a part of the closed loop. In FIG. 4(b), the film thickness of the narrower range can be measured. Therefore, accuracy of polishing end point detection can be improved.

FIG. 5 illustrates one example of a dimension of the eddy current sensor 1-50. As one example of the dimension of the eddy current sensor 1-50, a length L1 in a width direction is 3 mm, and a length L2 in an axial direction is 4 mm. A thickness L3 of the core part of the eddy current sensor 1-50 is 0.5 mm.

It is preferable to manufacture the core part 1-60 using a high permeability material (for example, ferrite, amorphous, permalloy, supermalloy, or Mu-metal) of a high relative permeability, for example. Conducting wires used in the detection coils 1-631 and 632, the excitation coil 1-62, and the dummy coils 1-641 and 642 are copper, manganin wires or nichrome wires. By using the manganin wires or the nichrome wires, temperature change of electric resistance or the like is reduced and temperature characteristics are improved.

FIG. 6 is a sectional view illustrating an outer peripheral part 1-210 made of a magnetic body or a metal and arranged at an outer periphery of the eddy current sensor 1-50 illustrated in FIG. 5. The outer peripheral part 1-210 is arranged outside the core part 1-60 and outside a coil part 1-61 so as to surround the whole of the core part 1-60 and the coil part 1-61. FIG. 6 is a schematic diagram illustrating an example of arranging the outer peripheral part 1-210 which is a columnar shape member formed of a magnetic body or metal material around the eddy current sensor 1-50. FIG. 6(a) is a sectional view viewing from BB in FIG. 6(b), and FIG. 6(b) is a sectional view viewing from AA in FIG. 6(a).

In the case of covering with the magnetic body 1-210 the area except gaps 1-70 at an upper part and a lower part of the core part 1-60, the magnetic flux flows, as illustrated with an arrow 210a, from the inside of the magnetic body 1-210 or the core part 1-60 to the magnetic body 1-210. Therefore, since leakage of the magnetic flux to the outside of the magnetic body 1-210 decreases, convergence of the magnetic field can be improved. There is an effect of converging the magnetic field leaking to the outside of the eddy current sensor 1-50 on a side face inside the magnetic body 1-210. In addition, even in the case of covering the area with the outer peripheral part 1-210 made of the metal with high electric conductivity, the leakage of the magnetic flux to the outside decreases, and there is a shielding effect. In such a manner, by covering the periphery of the sensor with the magnetic body or the metal, a leakage magnetic field other than the gaps 1-70 is suppressed, a magnetic field converging effect is enhanced, and the metal film thickness in the smaller range can be measured. A material of the outer peripheral part 1-210 is, in the case of using the metal, SUS304 or aluminum, for example.

Internal spaces 1-300 and 302 of the outer peripheral part 1-210 may be filled with a non-magnetic body. The non-magnetic body is an insulating material, for example, an epoxy resin, a fluororesin or glass epoxy. A thickness L4 of the outer peripheral part 1-210 is, as illustrated in FIG. 6(b), about 2 mm. A thickness L5 of the insulating material between the cantilever part 1-67 and the outer peripheral part 1-210 is about 0.5 mm. When the outer peripheral part 1-210 is the metal, the outer peripheral part 1-210 is grounded by a metallic conducting wire. In this case, a magnetic shielding effect is stabilized and increased.

The outer peripheral part 1-210 includes, as illustrated in FIG. 7, at least one groove, four grooves 1-226 in the figure that extend in the axial direction of the sensor. FIG. 7 is a sectional view in an arrow CC in FIG. 6(a). In this way, cuts (grooves) 226 are made at the outer peripheral part 1-210, and generation of an eddy current 1-228 in a peripheral direction in the outer peripheral part 1-210 is prevented. It is because the eddy current generated at the conductive film which is the measurement object becomes weak when the eddy current 1-228 is generated in the peripheral direction of the outer peripheral part 1-210. The magnetic field 1-208 used for detection (illustrated in FIG. 5 is the magnetic field generated in the axial direction of the core part 1-60 and is different from the eddy current in the peripheral direction generated at the outer peripheral part 1-210 so that it is not shielded by the grooves 1-226 of the outer peripheral part 1-210. Only the eddy current 1-228 in the peripheral direction is shielded by the grooves 1-226.

Regarding the arrangement and length in the axial direction of the grooves 1-226, a short groove may be provided only at an upper end 1-241 of the outer peripheral part 1-210 as illustrated in FIG. 6(a), it may be over a half 240 of the length in the axial direction of the outer peripheral part 1-210 as illustrated in FIG. 6(b), or it may be over an entire length 1-242 of the length in the axial direction of the outer peripheral part 1-210 further. It can be selected depending on how much eddy current the eddy current 1-228 generated in the peripheral direction of the outer peripheral part 1-210 generates at the conductive film which is the measurement object.

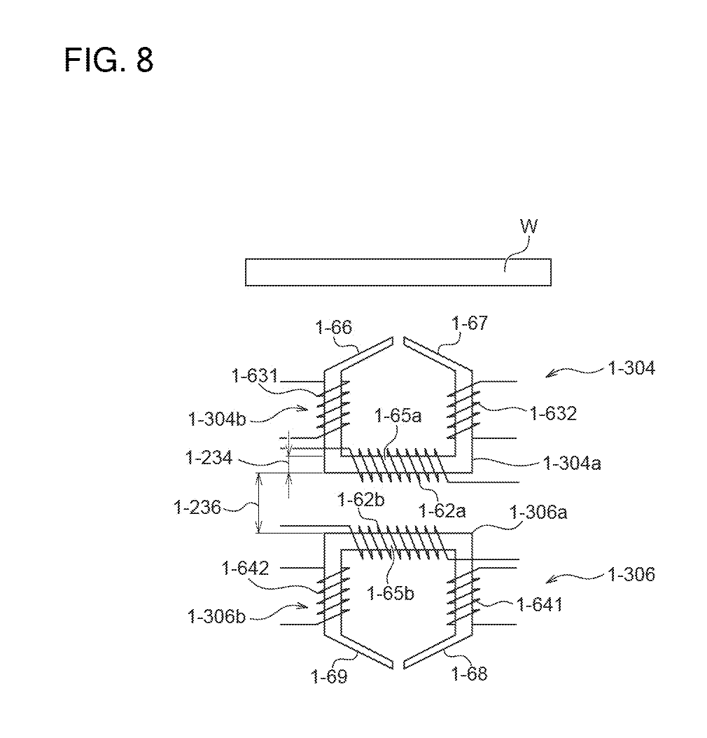

FIG. 8 illustrates another embodiment of the eddy current sensor. In FIG. 8, the eddy current sensor includes a sensor part 1-304, and a dummy part 1-306 arranged in the vicinity of the sensor part 1-304. The sensor part 1-304 includes a sensor core part 1-304a and a sensor coil part 1-304b. The sensor core part 1-304a includes a sensor common part 1-65a, and the first cantilever part 1-66 and the second cantilever part 1-67 connected to the sensor common part 1-65a. The first cantilever part 1-66 and the second cantilever part 1-67 are arranged facing each other.

The dummy part 1-306 includes a dummy core part 1-306a and a dummy coil part 1-306b, and the dummy core part 1-306a includes a dummy common part 1-65b and the third cantilever part 1-69 and the fourth cantilever part 1-68 connected to the dummy common part 1-65b. The third cantilever part 1-69 and the fourth cantilever part 1-68 are arranged facing each other.

The sensor coil part 1-304b includes a sensor excitation coil 1-62a that is arranged at the sensor common part 1-65a and forms the eddy current at the conductive film W, and the first detection coil 1-631 that is arranged at the first cantilever part 1-66 and detects the eddy current formed at the conductive film W.

The dummy part 1-306 includes a dummy excitation coil 1-62b arranged at the dummy common part 1-65b, and the first dummy coil 1-642 arranged at the third cantilever part 1-69. The ends of the first cantilever part 1-66 and the second cantilever part 1-67 far from parts where the first cantilever part 1-66 and the second cantilever part 1-67 are connected with the sensor common part 1-65a are close and adjacent to each other. The ends of the third cantilever part 1-69 and the fourth cantilever part 1-68 far from parts where the third cantilever part 1-69 and the fourth cantilever part 1-68 are connected with the dummy common part 1-65b are close and adjacent to each other.

The sensor part 1-304 and the dummy part 1-306 are arranged in the order of the sensor part 1-304 and the dummy part 1-306 from a position near the substrate W to a position far from the substrate W.

Further, the sensor part 1-304 includes the second detection coil 1-632 that is arranged at the second cantilever part 1-67 and detects the eddy current formed at the conductive film W. The dummy part 1-306 includes the second dummy coil 1-641 arranged at the fourth cantilever part 1-68.

Further, the sensor part 1-304 is tapered toward the conductive film W, however, the dummy part 1-306 is tapered toward the opposite of the conductive film W.

In the figure, differently from the embodiment in FIG. 4, two separated core parts are used. In the case of the figure, the detection coils 1-631 and 632 and the dummy coils 1-641 and 642 are provided in the similar arrangement inside the different core parts. In the embodiment in FIG. 4, the detection coil 1-63 and the dummy coil 1-64 are arranged inside one core part. In FIG. 8, differently from the embodiment in FIG. 4, the dummy coils 1-641 and 642 are far from the substrate W so that they are not easily affected by the substrate W. Therefore, there is an advantage that the dummy coils 1-641 and 642 can accurately achieve the object of the dummy coils 1-641 and 642 to generate reference signals during measurement.

Note that, regarding a distance 1-236 between the sensor part 1-304 and the dummy part 1-306, it is preferable that the distance 1-236 is longer than a core bottom part thickness 1-234 in order to avoid magnetic field interference of the cores of each other. As a different method, a metal or the like may be inserted to the part of the distance 1-236 to perform shielding.

Note that, in the embodiments in FIG. 1 to FIG. 8, the common part 1-65, the first cantilever part 1-66 and the second cantilever part 1-67 may configure a triangle as a whole. At the time, each of the common part 1-65, the first cantilever part 1-66 and the second cantilever part 1-67 corresponds to one side of the triangle. Similarly, the common part 1-65, the third cantilever part 1-69 and the fourth cantilever part 1-68 may configure a triangle as a whole.

Note that, in the embodiments in FIG. 1 to FIG. 8, a frequency of electric signals applied to the excitation coil 1-62 is a frequency where a detection circuit does not oscillate which detects the eddy current formed at the conductive film, based on output of the eddy current sensor. By utilizing the frequency that is not oscillated, an operation of the circuit is stabilized.

In addition, a winding number of the conducting wires of the detection coil, the excitation coil and the dummy coil can be set to be a frequency not oscillated by the detection circuit which detects the eddy current formed at the conductive film based on the output of the eddy current sensor.

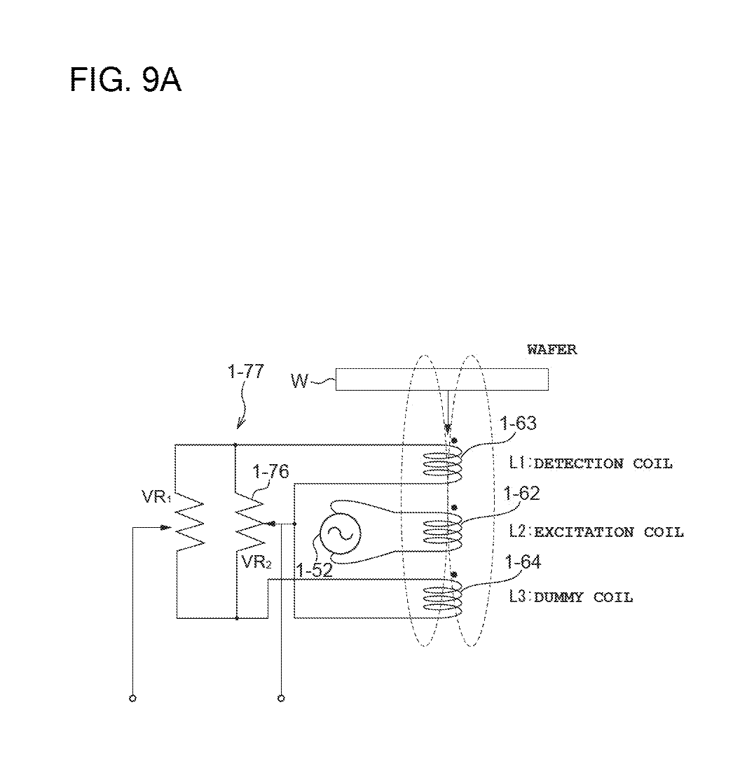

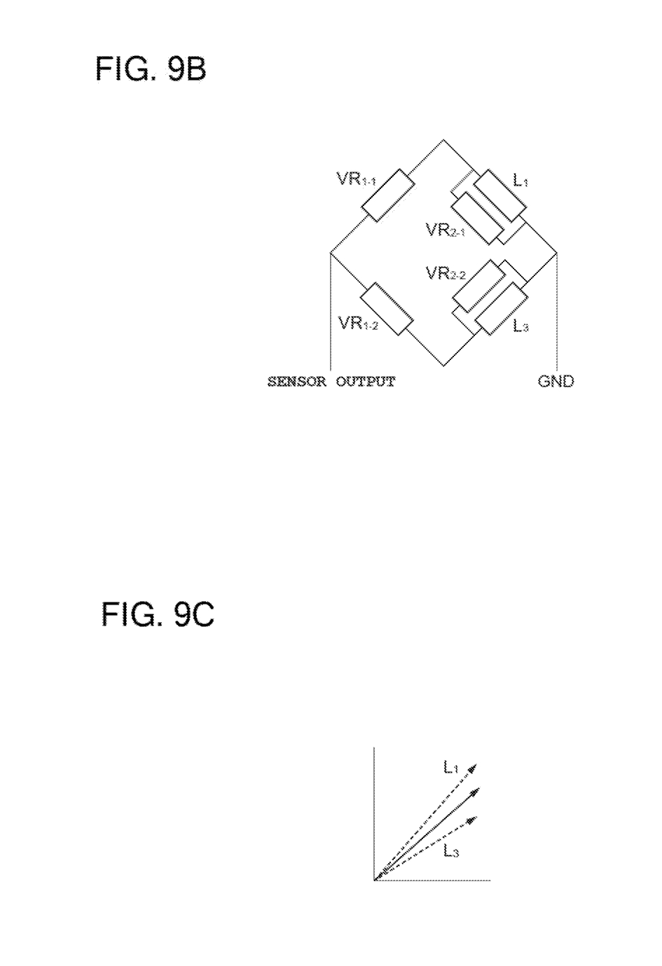

FIGS. 9A, 9B and 9C are schematic diagrams illustrating a connection example of the individual coils in the eddy current sensor. As illustrated in FIG. 9A, the detection coil 1-631 and the dummy coil 1-642 are connected in phases opposite to each other. While FIG. 9A illustrates a connection example for the case of the detection coil 1-631 and the dummy coil 1-642, a connection method is the same also for the case of the detection coil 1-632 and the dummy coil 1-641. Hereinafter, the case of the detection coil 1-631 and the dummy coil 1-642 will be described.

The detection coil 1-631 and the dummy coil 1-642 configure a serial circuit of the opposite phase as described above, and both ends thereof are connected to a resistor bridge circuit 1-77 including a variable resistor 76. The excitation coil 1-62 is connected to the AC signal source 1-52 and generates an alternating magnetic flux, thereby forming the eddy current at the metal film (or conductive film) mf arranged in the vicinity. By adjusting a resistance value of the variable resistor 1-76, an output voltage of the serial circuit formed of the coils 1-631 and 642 can be adjusted to be zero when the metal film (or conductive film) is not present. Signals of L₁ and L₃ are adjusted to be in phase by the variable resistors 1-76 (VR₁, VR₂) that enter in parallel each of the coils 1-631 and 642. That is, in an equivalent circuit in FIG. 9B, the variable resistors VR₁ (=VR₁₋₁+VR₁₋₂) and VR₂ (=VR₂₋₁+VR₂₋₂) are adjusted so as to satisfy

VR₁₋₁×(VR₂₋₂+jωL₃)=VR₁₋₂×(VR₂₋₁+jωL₁) (1).

Thus, as illustrated in FIG. 9C, the signals (indicated by dotted lines in the figure) of L₁ and L₃ before adjustment are turned to the signals (indicated by a solid line in the figure) of the same phase and same amplitude.

Then, when the metal film (or conductive film) is present in the vicinity of the detection coil 1-631, the magnetic flux generated by the eddy current formed in the metal film (or conductive film) interlinks with the detection coil 1-631 and the dummy coil 1-642, and since the detection coil 1-631 is arranged at the position near the metal film (or conductive film), balance of induction voltages generated in both coils 1-631 and 642 is lost, and thus an interlinkage magnetic flux formed by the eddy current of the metal film (or conductive film) can be detected. That is, by separating the serial circuit of the detection coil 1-631 and the dummy coil 1-642 from the excitation coil 1-62 connected to the AC signal source and adjusting the balance in the resistor bridge circuit, a zero point can be adjusted. Therefore, since the eddy current flowing to the metal film (or conductive film) can be detected from a zero state, detection sensitivity of the eddy current in the metal film (or conductive film) can be improved. Thus, the size of the eddy current formed at the metal film (or conductive film) can be detected in a wide dynamic range.

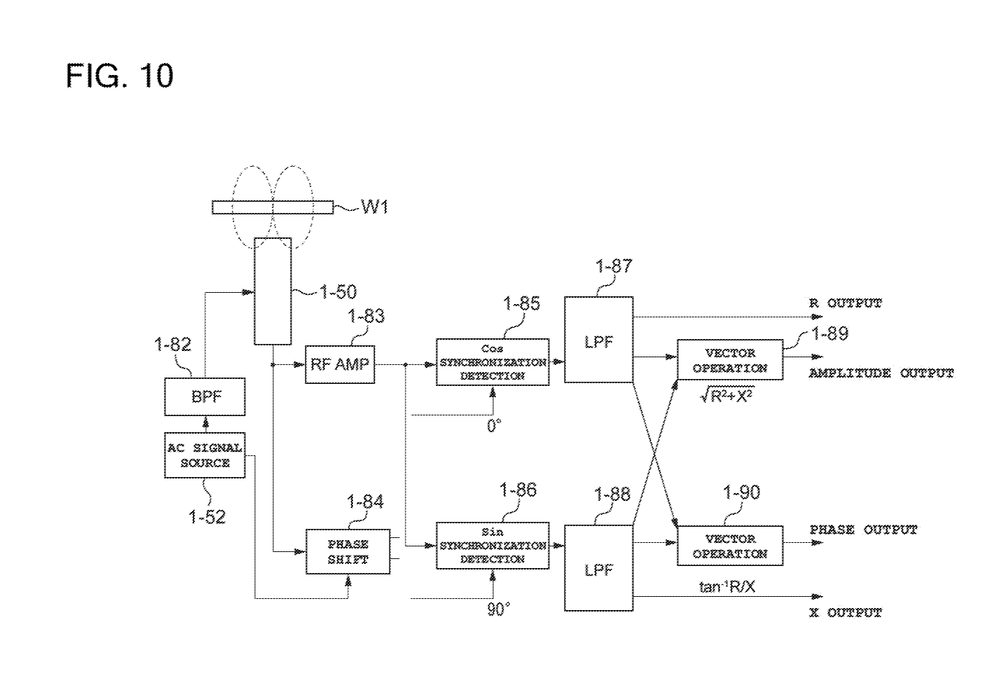

FIG. 10 is a block diagram illustrating a synchronization detection circuit of the eddy current sensor.

FIG. 10 illustrates a measurement circuit example of the impedance Z viewing the side of the eddy current sensor 1-50 from the side of the AC signal source 1-52. In a measurement circuit of the impedance Z illustrated in FIG. 10, a resistance component (R), a reactance component (X), amplitude output (Z) and phase output (tan⁻¹ R/X) accompanying the change of the film thickness can be taken out.

As described above, the signal source 1-52 that supplies AC signals to the eddy current sensor 1-50 arranged in the vicinity of the semiconductor wafer W where the metal film (or conductive film) mf of the detection object is formed is the oscillator of the fixed frequency formed of the crystal oscillator, and supplies the voltages of the fixed frequencies of 2 MHz or 8 MHz, for example. The AC voltage formed in the signal source 1-52 is supplied through a band-pass filter 1-82 to the eddy current sensor 1-50. Signals detected at a terminal of the eddy current sensor 1-50 are made to pass through a high frequency amplifier 1-83 and a phase shift circuit 1-84, and cos components and sin components of detection signals are taken out by a synchronization detection part formed of a cos synchronization detection circuit 1-85 and a sin synchronization detection circuit 1-86. Here, for oscillation signals formed in the signal source 1-52, two signals of in-phase components (0°) and orthogonal components (90°) of the signal source 1-52 are formed by the phase shift circuit 1-84 and are introduced into the cos synchronization detection circuit 1-85 and the sin synchronization detection circuit 1-86 respectively, and the above-described synchronization detection is carried out.

For synchronization detected signals, unneeded high frequency components higher than signal components are removed by low-pass filters 1-87 and 1-88, and resistance component (R) output which is cos synchronization detection output and reactance component (X) output which is sin synchronization detection output are taken out. In addition, by a vector operation circuit 89, amplitude output (R²+X²)^{1/2} is obtained from the resistance component (R) output and the reactance component (X) output. Also, by a vector operation circuit 90, phase output (tan⁻¹ R/X) is obtained similarly from the resistance component output and the reactance component output. Here, a measuring device main body is provided with various kinds of filters in order to eliminate noise components of sensor signals. To the various kinds of filters, cutoff frequencies corresponding to each of them are set, and by setting the cutoff frequency of the low-pass filter in the range of 0.1 to 10 Hz, for example, the noise components coexisting in the sensor signals during polishing are eliminated, and the metal film (or conductive film) of the measurement object can be highly accurately measured.

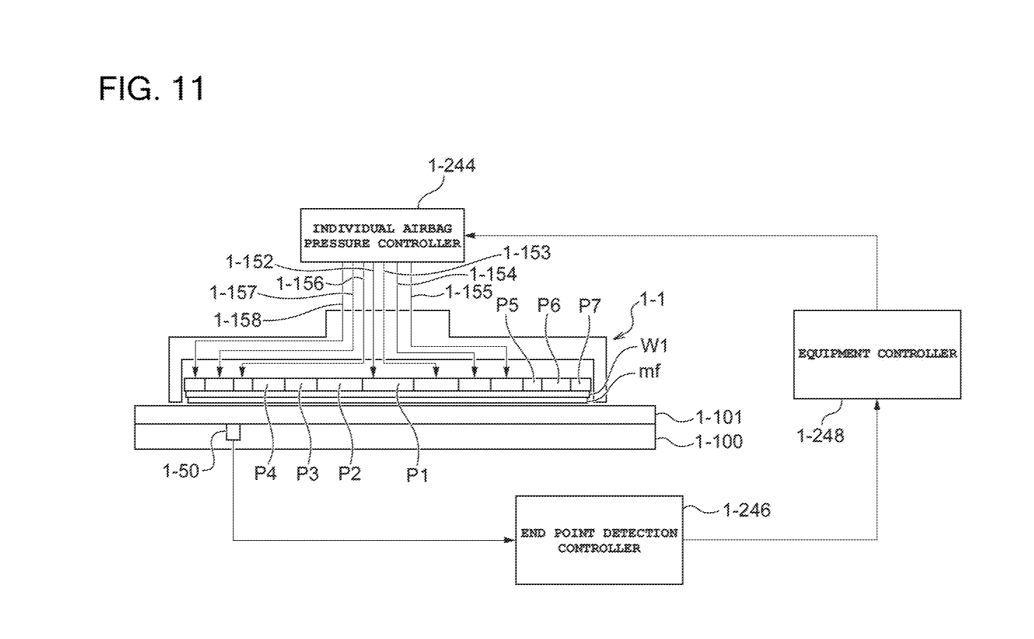

Note that, in the polishing device to which the individual embodiments described above are applied, as illustrated in FIG. 11, a plurality of pressure chambers (airbags) P1 to P7 can be provided in space inside the top ring 1-1, and an internal pressure of the pressure chambers P1 to P7 can be adjusted. That is, inside the space formed on an inner side of the top ring 1-1, the plurality of pressure chambers P1 to P7 are provided. The plurality of pressure chambers P1 to P7 include a circular pressure chamber P1 at the center and a plurality of annular pressure chambers P2 to P7 arranged concentrically on the outer side of the pressure chamber P1. The internal pressure of the individual pressure chambers P1 to P7 can be changed independently of each other by an individual airbag pressure controller 244. Thus, pressurizing force in individual areas of the substrate W at positions corresponding to the individual pressure chambers P1 to P7 can be independently adjusted.

In order to independently adjust the pressurizing force in the individual areas, it is needed to measure a wafer film thickness distribution by the eddy current sensor 1-50. As described below, the wafer film thickness distribution can be obtained from sensor output, a top ring rotation number and a table rotation number.

First, a track (scanning line) when the eddy current sensor 1-50 scans the surface of the semiconductor wafer will be described.

In one embodiment of the present invention, a rotation speed ratio of the top ring 1-1 and the polishing table 1-100 is adjusted so that the track drawn on the semiconductor wafer W by the eddy current sensor 1-50 within a predetermined period of time is roughly equally distributed over the entire surface of the semiconductor wafer W.

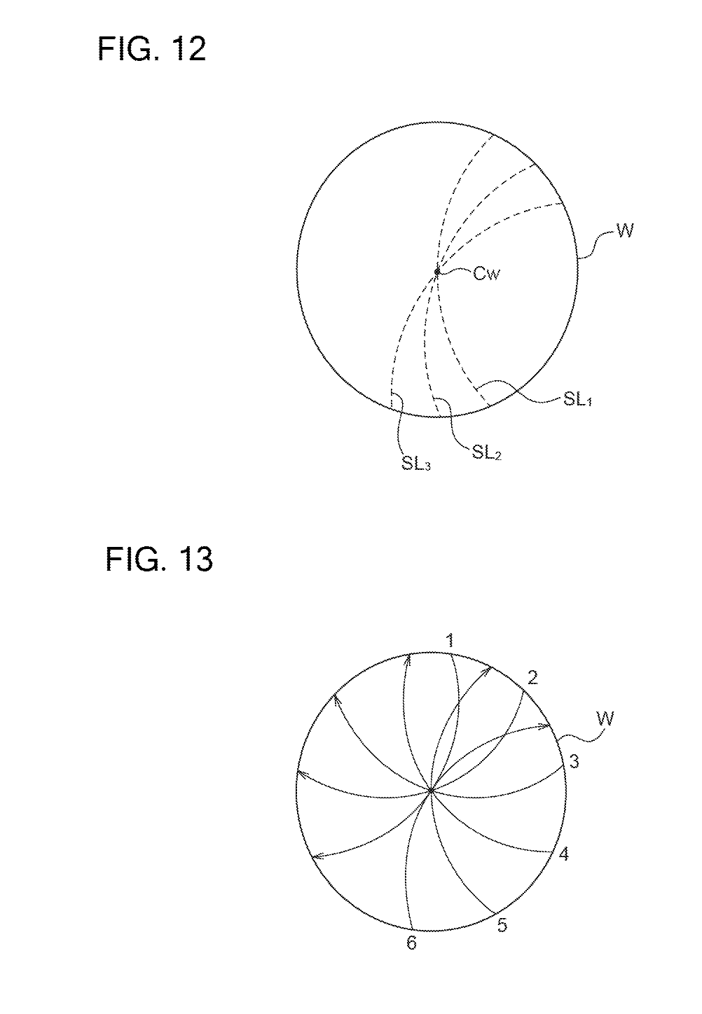

FIG. 12 is a schematic drawing illustrating the track that the eddy current sensor 1-50 performs a scan on the semiconductor wafer W. As illustrated in FIG. 12, the eddy current sensor 1-50 scans the surface (surface to be polished) of the semiconductor wafer W every time the polishing table 1-100 is rotated once, and when the polishing table 1-100 is rotated, the eddy current sensor 1-50 scans the surface to be polished of the semiconductor wafer W drawing the track roughly passing through the center Cw (the center of the top ring shaft 1-111) of the semiconductor wafer W. By making the rotation speed of the top ring 1-1 and the rotation speed of the polishing table 1-100 be different, the track of the eddy current sensor 1-50 on the surface of the semiconductor wafer W is changed like scanning lines SL₁, SL₂, SL₃, . . . accompanying the rotation of the polishing table 1-100 as illustrated in FIG. 12. Even in this case, as described above, since the eddy current sensor 1-50 is arranged at the position to pass through the center Cw of the semiconductor wafer W, the track drawn by the eddy current sensor 1-50 passes through the center Cw of the semiconductor wafer W every time.

FIG. 13 is a figure illustrating the track on the semiconductor wafer drawn by the eddy current sensor 1-50 within the predetermined period of time (5 seconds in this example) assuming that the rotation speed of the polishing table 1-100 is 70 min⁻¹ and the rotation speed of the top ring 1-1 is 77 min⁻¹. As illustrated in FIG. 13, under this condition, since the track of the eddy current sensor 1-50 rotates by 36 degrees every time the polishing table 1-100 is rotated once, the sensor track is rotated half around on the semiconductor wafer W every time the scan is performed five times. When a curve of the sensor track is also taken into consideration, when the eddy current sensor 1-50 scans the semiconductor wafer W six times within the predetermined period of time, the eddy current sensor 1-50 roughly equally scans the entire surface of the semiconductor wafer W. For each track, the eddy current sensor 1-50 can perform measurement for several hundreds of times. On the entire semiconductor wafer W, for example, the film thickness is measured at 1000 to 2000 measurement points to obtain the film thickness distribution.

While the above-described example illustrates the case that the rotation speed of the top ring 1-1 is faster than the rotation speed of the polishing table 1-100, also in the case that the rotation speed of the top ring 1-1 is slower than the rotation speed of the polishing table 1-100 (for example, the rotation speed of the polishing table 1-100 is 70 min⁻¹ and the rotation speed of the top ring 1-1 is 63 min⁻¹), the sensor track is just rotated in an opposite direction, and a point that the track drawn on the surface of the semiconductor wafer W by the eddy current sensor 1-50 within the predetermined period of time is distributed over the entire periphery of the surface of the semiconductor wafer W is the same as the above-described example.

A method of controlling the pressurizing force in the individual areas of the substrate W based on the obtained film thickness distribution will be described below. As illustrated in FIG. 11, the eddy current sensor 1-50 is connected to an end point detection controller 1-246, and the end point detection controller 1-246 is connected to an equipment controller 1-248. Output signals of the eddy current sensor 1-50 are sent to the end point detection controller 1-246. The end point detection controller 1-246 executes required processing (arithmetic processing/correction) to the output signals of the eddy current sensor 1-50 and generates monitoring signals (film thickness data corrected by the end point detection controller 1-246). The end point detection controller 1-246 operates the internal pressure of the individual pressure chambers P1 to P7 inside the top ring 1-1 based on the monitoring signals. That is, the end point detection controller 1-246 determines the force of pressurizing the substrate W by the top ring 1-1, and transmits the pressurizing force to the equipment controller 1-248. The equipment controller 1-248 issues a command to the individual airbag pressure controller 1-244 so as to change the pressurizing force to the substrate W of the top ring 1-1. The distribution of the film thickness of the substrate W detected by a film thickness sensor or signals corresponding to the film thickness is stored in the equipment controller 1-248. Then, according to the distribution of the film thickness of the substrate W or the signals corresponding to the film thickness transmitted from the end point detection controller 1-246, in the equipment controller 1-248, based on a polishing amount for a pressurizing condition stored in a database of the equipment controller 1-248, the pressurizing condition of the substrate W for which the distribution of the film thickness or the signals corresponding to the film thickness is detected is determined, and transmitted to the individual airbag pressure controller 1-244.

The pressurizing condition of the substrate W is determined as follows, for example. Based on information regarding a wafer area where the polishing amount is affected when the pressure of each airbag is changed, a film thickness average value of each wafer area is calculated. The wafer area to be affected is calculated from an experiment result or the like and inputted to the database of the equipment controller 1-248 beforehand. The pressure to an airbag part corresponding to the wafer area where the film is thin is lowered, the pressure to an airbag part corresponding to the wafer area where the film is thick is raised, and the airbag pressure is controlled so as to uniformize the film thickness of the individual areas. At the time, a polishing rate may be calculated from the past film thickness distribution result and may be turned to an indicator of the pressure to be controlled.

Next, a control flow of the pressurizing force of the individual areas of the substrate W will be described.

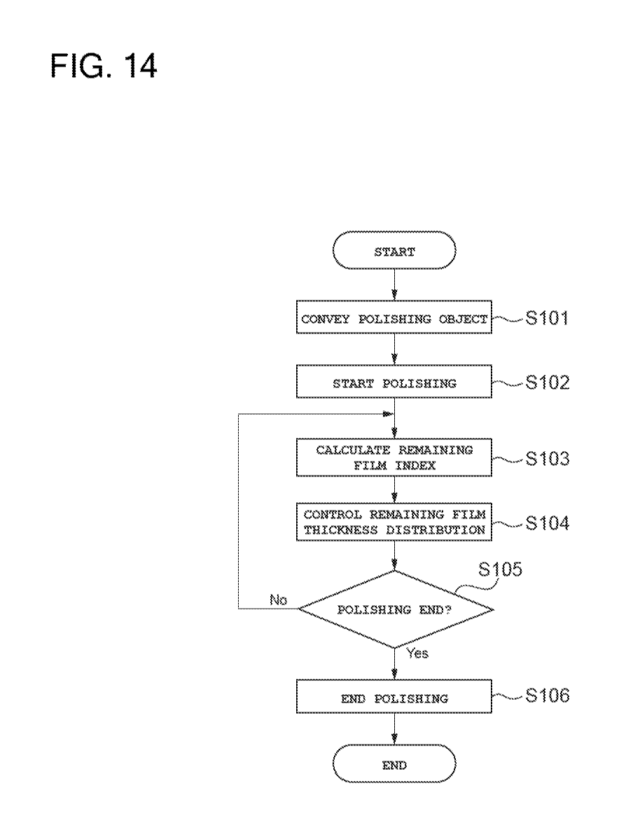

FIG. 14 is a flowchart illustrating one example of the operation of pressure control to be performed during polishing. First, the polishing device conveys the substrate W to a polishing position (step S101). Then, the polishing device starts polishing the substrate W (step S102).

Subsequently, the end point detection controller 1-246 calculates a remaining film index (film thickness data expressing a remaining film amount) for the individual areas of the polishing object while the substrate W is being polished (step S103). Then, the equipment controller 1-248 controls the distribution of the remaining film thickness based on the remaining film index (step S104).

Specifically, the equipment controller 1-248 independently controls the pressures to be applied to the individual areas on a back surface of the substrate W (that is, the pressures inside the pressure chambers P1 to P7), based on the remaining film indexes calculated for the individual areas. Note that a polishing characteristic (polishing speed with respect to the pressure) sometimes becomes instable due to alteration of a film surface layer to be polished of the substrate W or the like in an initial period of polishing. In such a case, predetermined waiting time may be provided before the first control is performed after polishing is started.

Subsequently, an end point detector determines whether or not to end the polishing of the polishing object based on the remaining film index (step S105). When the end point detection controller 1-246 determines that the remaining film index has not reached a target value set beforehand (step S105, No), processing returns to step S103.

On the other hand, when the end point detection controller 1-246 determines that the remaining film index has reached the target value set beforehand (step S105, Yes), the equipment controller 1-248 ends the polishing of the polishing object (step S106). In steps S105 to 106, it is also possible to end the polishing by determining whether or not predetermined time has elapsed from the polishing start. According to the present embodiment, in the eddy current sensor, since a space resolution is improved, an effective range of eddy current sensor output spreads to the narrow area such as an edge so that measurement points for each area of the substrate W increase, controllability of the polishing can be improved, and polishing flatness of the substrate can be improved.

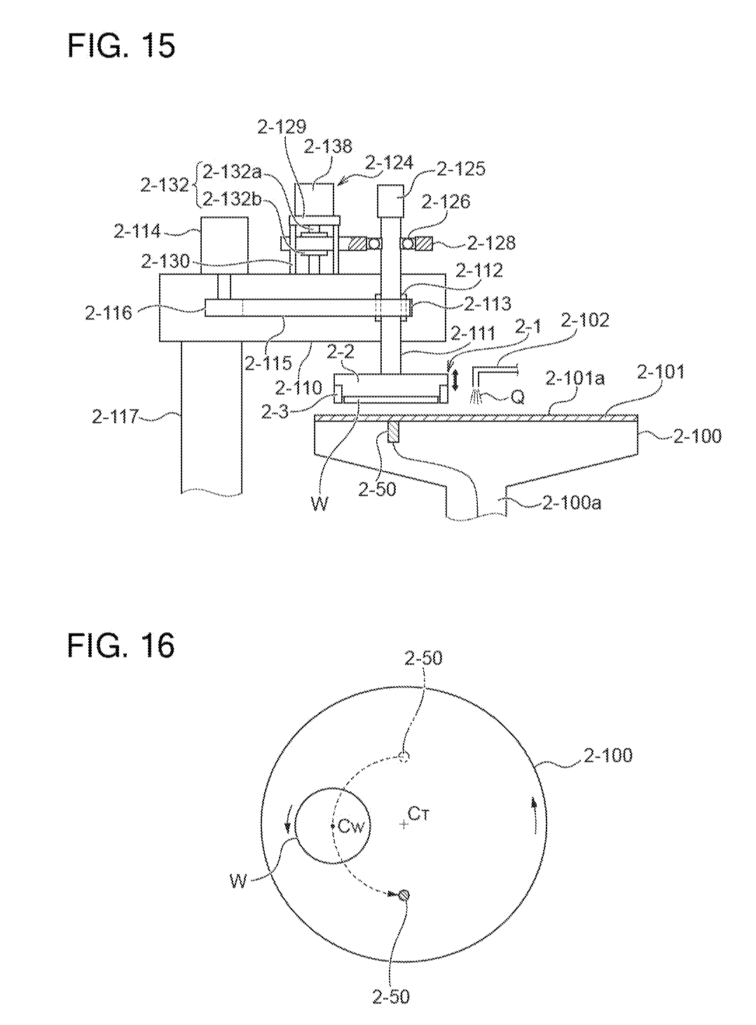

FIG. 15 is a schematic diagram illustrating an entire configuration of a polishing device in one embodiment relating to the present invention. As illustrated in FIG. 15, the polishing device includes a polishing table 2-100 and a top ring (holding part) 1 that holds a substrate such as a semiconductor wafer which is a polishing object and pressurizes it to a polishing surface on the polishing table.

The polishing table 2-100 is connected to a motor (not shown in the figure) which is a drive part arranged at the lower part through a table shaft 2-100a, and is rotatable around the table shaft 2-100a. A polishing pad 2-101 is stuck to an upper surface of the polishing table 2-100, and a surface 2-101a of the polishing pad 2-101 configures a polishing surface that polishes a semiconductor wafer W. A polishing liquid supply nozzle 2-102 is installed above the polishing table 2-100, and a polishing liquid Q is supplied onto the polishing pad 2-101 on the polishing table 2-100 by the polishing liquid supply nozzle 2-102. As illustrated in FIG. 15, an eddy current sensor 2-50 is embedded inside the polishing table 2-100.

The top ring 2-1 is basically configured from a top ring main body 2-2 that pressurizes the semiconductor wafer W to the surface 2-101a, and a retainer ring 2-3 that holds an outer peripheral edge of the semiconductor wafer W and prevents the semiconductor wafer W from jumping out of the top ring.

The top ring 2-1 is connected to a top ring shaft 2-111, and the top ring shaft 2-111 is vertically moved with respect to a top ring head 2-110 by a vertical movement mechanism 2-124. By the vertical movement of the top ring shaft 2-111, the entire top ring 2-1 is elevated and lowered and positioned with respect to the top ring head 2-110. Note that a rotary joint 2-125 is attached to an upper end of the top ring shaft 2-111.

The vertical movement mechanism 2-124 that vertically moves the top ring shaft 2-111 and the top ring 2-1 includes a bridge 2-128 that rotatably supports the top ring shaft 2-111 through a bearing 2-126, a ball screw 2-132 attached to the bridge 2-128, a support base 2-129 supported by a column 130, and an AC servo motor 2-138 provided on the support base 2-129. The support base 2-129 that supports the servo motor 2-138 is fixed through the column 2-130 to the top ring head 2-110.

The ball screw 2-132 includes a screw shaft 2-132a connected to the servo motor 2-138, and a nut 2-132b to which the screw shaft 2-132a is screwed. The top ring shaft 2-111 is vertically moved integrally with the bridge 2-128. Therefore, when the servo motor 2-138 is driven, the bridge 2-128 is vertically moved through the ball screw 2-132, and thus the top ring shaft 2-111 and the top ring 2-1 are vertically moved.

In addition, the top ring shaft 2-111 is connected to a rotary cylinder 2-112 through a key (not shown in the figure). The rotary cylinder 2-112 includes a timing pulley 2-113 on the outer peripheral part. A motor 2-114 for the top ring is fixed to the top ring head 2-110, and the timing pulley 2-113 is connected to a timing pulley 2-116 provided on the motor 2-114 for the top ring through a timing belt 2-115. Therefore, by rotationally driving the motor 2-114 for the top ring, the rotary cylinder 2-112 and the top ring shaft 2-111 are integrally rotated through the timing pulley 2-116, the timing belt 2-115 and the timing pulley 2-113, and the top ring 2-1 is rotated. Note that the top ring head 2-110 is supported by a top ring head shaft 2-117 rotatably supported by a frame (not shown in the figure).

In the polishing device configured as illustrated in FIG. 15, the top ring 2-1 can hold a substrate such as the semiconductor wafer W on the lower surface. The top ring head 2-110 is configured so as to turn around the top ring head shaft 2-117, and the top ring 2-1 holding the semiconductor wafer W on the lower surface is moved from a position to receive the semiconductor wafer W to an upper part of the polishing table 2-100 by turning of the top ring head 2-110. Then, the top ring 2-1 is lowered and the semiconductor wafer W is pressurized to the surface (polishing surface) 101a of the polishing pad 2-101. At the time, the top ring 2-1 and the polishing table 2-100 are rotated, and the polishing liquid is supplied from the polishing liquid supply nozzle 2-102 provided above the polishing table 2-100 onto the polishing pad 2-101. In such a manner, the semiconductor wafer W is brought into slidable contact with the polishing surface 2-101a of the polishing pad 2-101, and the surface of the semiconductor wafer W is polished.

FIG. 16 is a plan view illustrating a relationship of the polishing table 2-100, the eddy current sensor 2-50 and the semiconductor wafer W. As illustrated in FIG. 16, the eddy current sensor 2-50 is installed at a position to pass through the center Cw of the semiconductor wafer W during polishing which is held by the top ring 2-1. A sign C_{T} is a rotation center of the polishing table 2-100. For example, the eddy current sensor 2-50 can detect a metal film (conductive film) such as a Cu layer of the semiconductor wafer W continuously on a passing track (scanning line), while passing through a lower part of the semiconductor wafer W.

Next, the eddy current sensor 2-50 provided in the polishing device relating to one embodiment of the present invention will be described more in detail using the attached drawings.

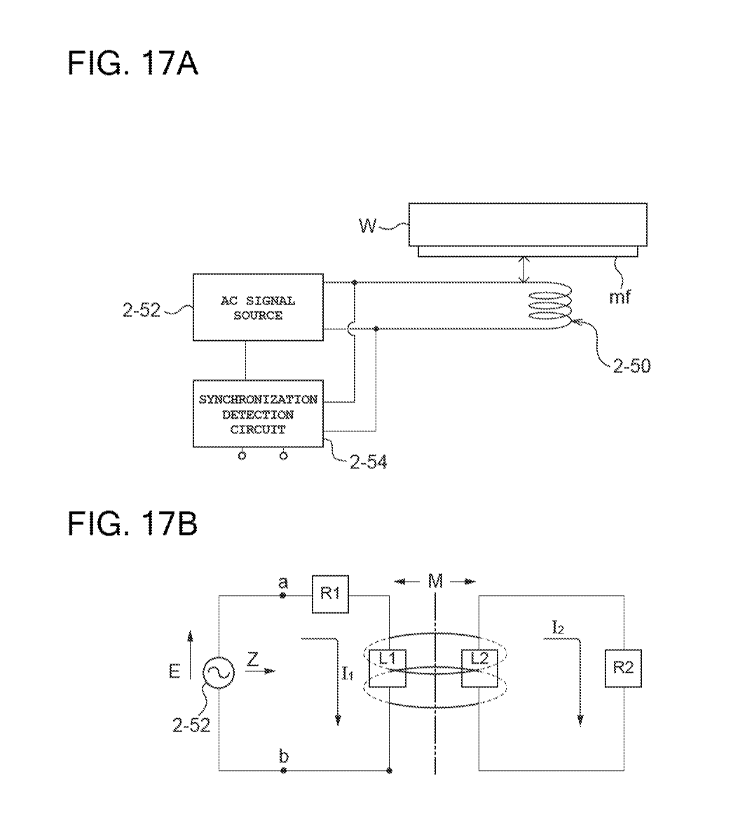

FIGS. 17A and 17B are diagrams illustrating a configuration of the eddy current sensor 2-50, FIG. 17A is a block diagram illustrating the configuration of the eddy current sensor 2-50, and FIG. 17B is an equivalent circuit diagram of the eddy current sensor 2-50.

As illustrated in FIG. 17A, the eddy current sensor 2-50 is arranged in the vicinity of a metal film (or conductive film) mf of a detection object, and an AC signal source 2-52 is connected to the coil. Here, the metal film (or conductive film) mf of the detection object is a thin film of Cu, Al, Au, W or the like formed on the semiconductor wafer W, for example. The eddy current sensor 2-50 is arranged in the vicinity of about 1.0 to 4.0 mm, for example, with respect to the metal film (or conductive film) of the detection object.

As the eddy current sensor, there are a frequency type in which an oscillation frequency is changed by generation of an eddy current in a metal film (or conductive film) mf and the metal film (or conductive film) is detected from the frequency change, and an impedance type in which an impedance is changed and the metal film (or conductive film) is detected from the impedance change. That is, in the frequency type, in an equivalent circuit illustrated in FIG. 17B, by the change of an eddy current I₂, an impedance Z is changed, and when the oscillation frequency of a signal source (variable frequency oscillator) 52 changes, the change of the oscillation frequency is detected in a detection circuit 54, and the change of the metal film (or conductive film) can be detected. In the impedance type, in the equivalent circuit illustrated in FIG. 17B, by the change of the eddy current I₂, the impedance Z is changed, and when the impedance Z in the view from the signal source (fixed frequency oscillator) 52 changes, the change of the impedance Z is detected in the detection circuit 54, and the change of the metal film (or conductive film) can be detected.

In the eddy current sensor of the impedance type, signal outputs X, Y, a phase, and a combined impedance Z are taken out as described later. From a frequency F or impedances X, Y or the like, measurement information of a metal film (or conductive film) Cu, Al, Au, W is obtained. The eddy current sensor 2-50 can be incorporated at a position near the surface inside the polishing table 2-100 as illustrated in FIG. 15, is positioned to face the semiconductor wafer of the polishing object through the polishing pad, and can detect the change of the metal film (or conductive film) from the eddy current flowing to the metal film (or conductive film) on the semiconductor wafer.

For a frequency of the eddy current sensor, a single radio wave, a mixed radio wave, an AM modulated radio wave, an FM modulated radio wave, sweep output of a function generator or a plurality of oscillation frequency sources can be used, and it is preferable to select an oscillation frequency or a modulation system with excellent sensitivity matched with a film kind of the metal film.

Hereinafter, the eddy current sensor of the impedance type will be specifically described. The AC signal source 2-52 is an oscillator of a fixed frequency of about 2 to 30 MHz, and a crystal oscillator is used, for example. Then, with an AC voltage supplied by the AC signal source 2-52, a current I₁ flows to the eddy current sensor 2-50. Since the current flows to the eddy current sensor 2-50 arranged in the vicinity of the metal film (or conductive film) mf, the magnetic flux is interlinked with the metal film (or conductive film) mf, thereby forming a mutual inductance M between them, and the eddy current I₂ flows in the metal film (or conductive film) mf. Here, reference character R1 denotes a primary side equivalent resistor including the eddy current sensor, and reference character L₁ denotes a primary side self-inductance similarly including the eddy current sensor. On the side of the metal film (or conductive film) mf, reference character R2 is an equivalent resistor corresponding to eddy current loss, and reference character L₂ is the self-inductance thereof. The impedance Z viewing an eddy current sensor side from terminals a and b of the AC signal source 2-52 changes depending on the size of the eddy current loss formed in the metal film (or conductive film) mf.

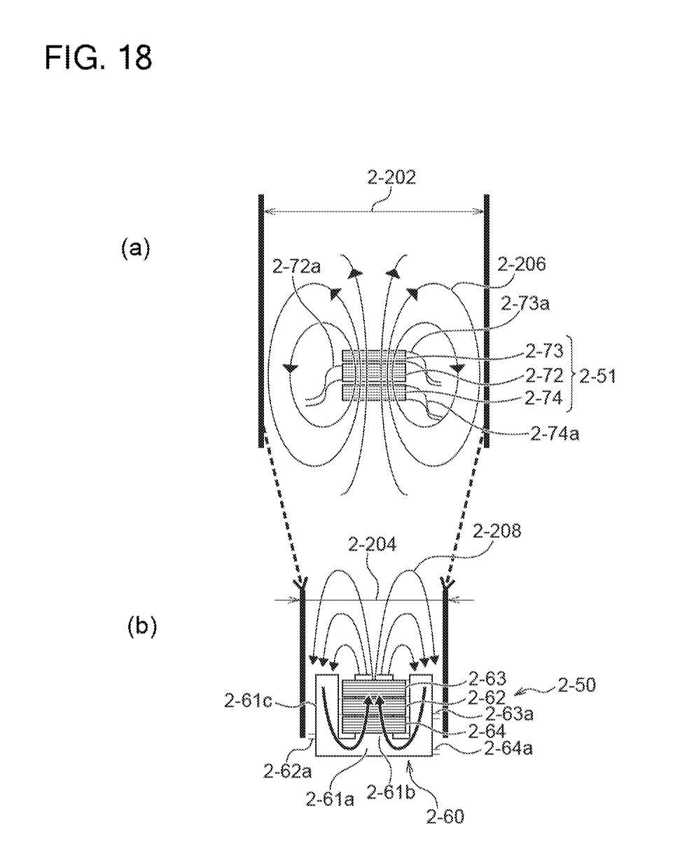

FIGS. 18(a) and 18(b) are diagrams illustrating a conventional eddy current sensor and the eddy current sensor of one embodiment of the present invention in comparison. FIG. 18(a) is a schematic diagram illustrating a configuration example of the conventional eddy current sensor, and FIG. 18(b) is a schematic diagram illustrating a configuration example of the eddy current sensor 2-50 of one embodiment of the present invention. In FIGS. 18(a) and 18(b), spreads of the respective magnetic fluxes when the conventional eddy current sensor and the eddy current sensor of one embodiment of the present invention are of the equal size are illustrated in comparison. As is clear from FIG. 18, it is understood that the magnetic flux is concentrated and the spread of the magnetic flux is narrow in the eddy current sensor 2-50 of one embodiment of the present invention in contrast with the conventional eddy current sensor.

As illustrated in FIG. 18(a), for a conventional eddy current sensor 2-51, a coil 2-72 for forming an eddy current at the metal film (or conductive film) and coils 2-73 and 74 for detecting the eddy current of the metal film (or conductive film) are separated, and it is configured by the three coils 2-72, 73 and 74 wound around a core (not shown in the figure). Here, the coil 2-72 at the center is an excitation coil connected to the AC signal source 2-52. The excitation coil 2-72 is supplied with an AC voltage from the AC signal source 2-52 and forms a magnetic field, and the magnetic field forms the eddy current at the metal film (or conductive film) mf on the semiconductor wafer (substrate) W arranged in the vicinity of the eddy current sensor 2-51. On the metal film (or conductive film) side of the core, the detection coil 2-73 is arranged, and detects the magnetic field generated by the eddy current formed at the metal film (or conductive film). On an opposite side of the detection coil 2-73 across the excitation coil 2-72, a dummy (balance) coil 2-74 is arranged.

In contrast, the eddy current sensor 2-50 of one embodiment of the present invention arranged in the vicinity of the substrate where the conductive film is formed is configured by a pot core 60 and the three coils 2-62, 63, and 64, as illustrated in FIG. 18(b). The pot core 60 which is a magnetic body includes a bottom surface part 2-61a, a magnetic core part 2-61b provided on a center of the bottom surface part 2-61a, and a peripheral wall part 2-61c provided around the bottom surface part 2-61a.

Of the three coils 1-62, 63 and 64, the coil 2-62 at the center is an excitation coil connected to the AC signal source 2-52. The excitation coil 2-62 forms the eddy current at the metal film (or conductive film) mf on the semiconductor wafer W arranged in the vicinity by a magnetic field formed by a voltage supplied from the AC signal source 2-52. On the metal film (or conductive film) side of the excitation coil 2-62, a detection coil 2-63 is arranged, and detects the magnetic field generated by the eddy current formed at the metal film (or conductive film). On the opposite side of the detection coil 2-63 across the excitation coil 2-62, a dummy coil 2-64 is arranged. The excitation coil 2-62 is arranged at the magnetic core part 2-61b, and forms the eddy current at the conductive film. The detection coil 2-63 is arranged at the magnetic core part 2-61b, and detects the eddy current formed at the conductive film. To the excitation coil 2-62, electric signals of a frequency being 2 MHz or higher are applied so as not to generate dimensional resonance of electromagnetic waves inside the magnetic core part 2-61b of the eddy current sensor 2-50.

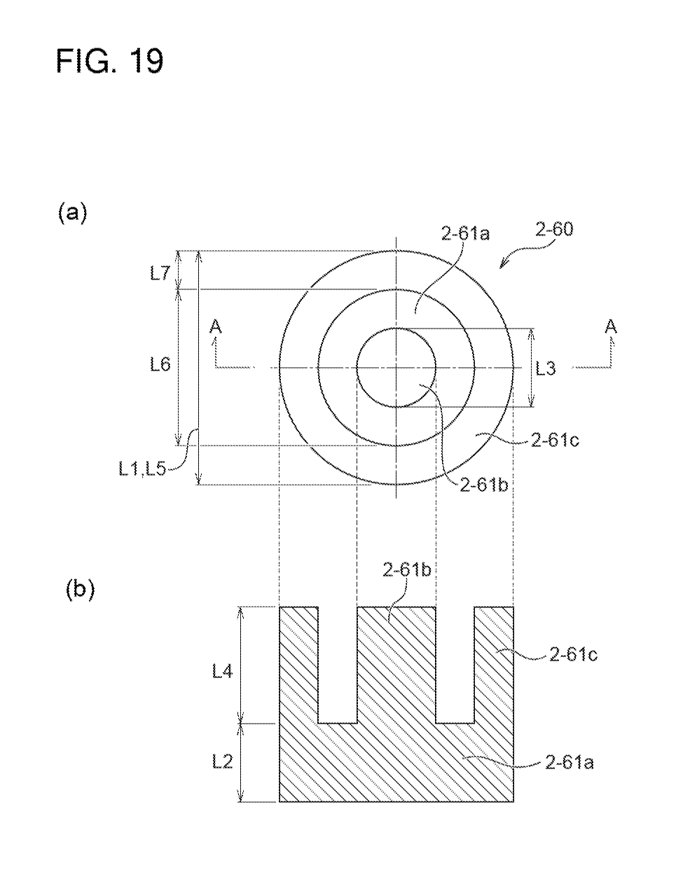

The frequency applied to the excitation coil 2-62 is a frequency which does not generate the dimensional resonance of the electromagnetic waves, and an arbitrary frequency can be applied. In the case of using Mn—Zn ferrite of which values of both permeability and permittivity are high for a magnetic core material of the eddy current sensor, a phenomenon that the electromagnetic waves inside the magnetic core become stationary waves under high frequency excitation of 1 MHz is known, and it is referred to as the dimensional resonance. Since the dimensional resonance is the resonance due to the magnetic path cross section of the magnetic core (magnetic core dimension), for a resonance frequency, by fixing an excitation frequency and changing the magnetic path cross section or fixing the magnetic path cross section and changing the excitation frequency, the dimensional resonance is generated. Since Ni—Zn ferrite of which the values of both permeability and permittivity are low is a material that hardly causes the dimensional resonance, in the present embodiment, the Ni—Zn ferrite is used. The relative permittivity of the Ni—Zn-based ferrite in the present embodiment is 5 to 15, the relative permeability is 1 to 300, and an outside dimension L3 (see FIG. 19) of the magnetic core part 2-61b is 50 mm or smaller. Further, electric signals of a frequency of 2 to 30 MHz are applied to the Ni—Zn ferrite so as not to generate the dimensional resonance of the electromagnetic waves.

The eddy current sensor includes the dummy coil 2-64 that is arranged at the magnetic core part 2-61b and detects the eddy current formed at the conductive film. The axial direction of the magnetic core part 2-61b is orthogonal to the conductive film on the substrate, and the detection coil 2-63, the excitation coil 2-62 and the dummy coil 2-64 are arranged at different positions in the axial direction of the magnetic core part 2-61b, and are arranged in the order of the detection coil 2-63, the excitation coil 2-62 and the dummy coil 2-64 from the position near the conductive film on the substrate toward the position far from the conductive film. From the detection coil 2-63, the excitation coil 2-62 and the dummy coil 2-64, lead wires 2-63a, 62a and 64a for connection with the outside are put out respectively.

A range 2-202 in FIG. 18(a) illustrates the spread of a magnetic flux 2-206 of the conventional eddy current sensor, and a range 2-204 in FIG. 18(b) illustrates the spread of a magnetic flux 2-208 of the eddy current sensor of one embodiment of the present invention. In FIG. 18(b), since the peripheral wall part 2-61c is the magnetic body, the magnetic flux 2-208 is converged inside the peripheral wall part 2-61c. Therefore, the spread of the magnetic flux 2-208 is limited, and the magnetic flux 2-208 becomes narrow. In the case of FIG. 18(a) of the conventional technique, the magnetic body is not present on the outer periphery of the coil, and the magnetic flux 2-206 is not converged. Therefore, the magnetic flux 2-206 spreads, the range 2-202 becomes wide, and the magnetic flux 2-206 becomes large.

In FIG. 18(b), since the electric signals of 2 MHz or higher are applied to the excitation coil 2-62 so as not to generate the dimensional resonance of the electromagnetic waves inside the magnetic core part 2-61b of the eddy current sensor 2-50, a strong magnetic flux is generated. Thus, the film thickness of the narrower range can be measured with the strong magnetic flux. Therefore, accuracy of polishing end point detection can be improved.

FIG. 19 illustrates a detailed shape of the pot core 60. FIG. 19(a) is a plan view, and FIG. 19(b) is a sectional view in an arrow AA in FIG. 19(a). The pot core 60 which is the magnetic body includes the bottom surface part 2-61a in a disk shape, the magnetic core part 2-61b in a columnar shape provided on the center of the bottom surface part 2-61a, and the peripheral wall part 2-61c in a cylindrical shape provided around the bottom surface part 2-61a. As one example of the dimension of the pot core 60, a diameter L1 of the bottom surface part 2-61a is 9 mm, a thickness L2 is 3 mm, a diameter L3 of the magnetic core part 2-61b is 3 mm, a height L4 is 5 mm, an outer diameter L5 of the peripheral wall part 2-61c is 9 mm, an inner diameter L6 is 5 mm, a thickness L7 is 2 mm, and a height L4 is 5 mm. The height L4 of the magnetic core part 2-61b and the height L4 of the peripheral wall part 2-61c are the same in FIG. 19, however, the height L4 of the magnetic core part 2-61b may be higher or lower than the height L4 of the peripheral wall part 2-61c. The peripheral wall part 2-61c is in the cylindrical shape with the same outer diameter in a height direction in FIG. 19, however, it may be in a tapered shape to be tapered in a direction away from the bottom surface part 2-61a, that is, toward a distal end.

In order not to leak the magnetic field around the pot core 60, it is preferable that the thickness L7 of the peripheral wall part 2-61c is a length equal to or longer than ½ of the diameter L3 of the magnetic core part 2-61b, and the thickness L2 of the bottom surface part 2-61a is a length equal to or longer than the diameter L3 of the magnetic core part 2-61b. The material of the pot core 60 is the Ni—Zn ferrite that hardly causes the dimensional resonance.

Conducting wires used in the detection coils 2-63, the excitation coil 2-62, and the dummy coil 2-64 are copper, manganin wires or nichrome wires. By using the manganin wires or the nichrome wires, temperature change of electric resistance or the like is reduced and temperature characteristics are improved.

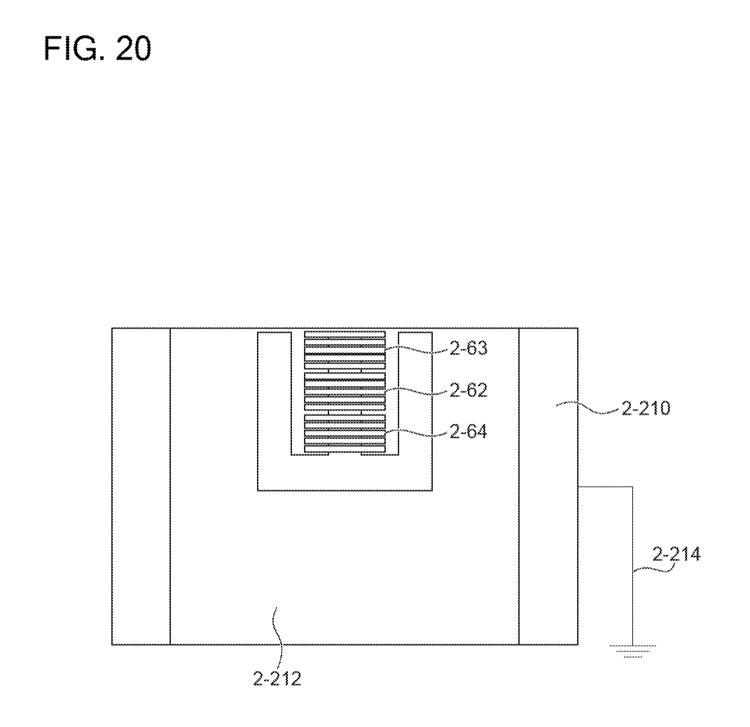

FIG. 20 is a sectional view illustrating a metallic outer peripheral part 2-210 arranged outside the peripheral wall part 2-61c of the eddy current sensor 2-50 illustrated in FIG. 18(b). FIG. 20 is a schematic diagram illustrating an example of arranging the outer peripheral part 2-210 which is a cylindrical member formed of a metal material around the eddy current sensor 2-50. As illustrated in FIG. 20, the periphery of the peripheral wall part 2-61c is surrounded by the outer peripheral part 2-210. The material of the peripheral wall part 2-61c is, for example, SUS304 or aluminum. An insulating material 2-212 (for example, an epoxy resin, a fluororesin or glass epoxy) is arranged around the peripheral wall part 2-61c, and the outer peripheral part 2-210 is arranged so as to surround the insulating material 2-212. In addition, the outer peripheral part 2-210 is grounded by a conducting wire 2-214. In this case, a magnetic shielding effect is stabilized and increased.

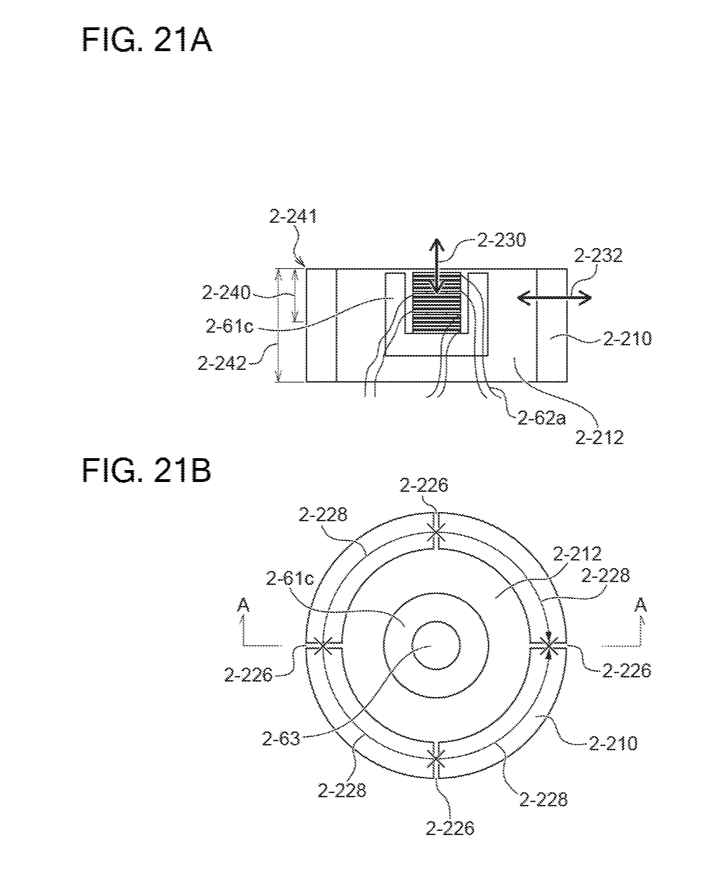

By surrounding the periphery of the peripheral wall part 2-61c by the metal, a magnetic field that spreads out is shielded, and a spatial resolution of the sensor 2-50 can be improved. The metal may be directly plated on the peripheral wall part 2-61c. The outer peripheral part 2-210 includes, as illustrated in FIGS. 21A and 21B, at least one groove, four grooves 2-226 in the figure that extend in the axial direction of the magnetic core part 2-61b. FIG. 21A is a sectional view, and FIG. 21B is a plan view. FIG. 21A is a sectional view in the arrow AA in FIG. 21B. In this way, cuts (grooves) 226 are made at the outer peripheral part 2-210, and generation of an eddy current 228 in a peripheral direction in the outer peripheral part 2-210 is prevented. It is because the eddy current generated at the conductive film which is the measurement object becomes weak when the eddy current 228 is generated in the peripheral direction of the outer peripheral part 2-210. A magnetic field 2-230 generated from a core center part used for detection is the magnetic field generated in the axial direction of the pot core 2-60 and is different from the eddy current in the peripheral direction generated at the outer peripheral part 2-210 so that it is not shielded by the grooves 2-226 of the outer peripheral part 2-210. Only a magnetic field 2-232 leaking to a side face is shielded by the grooves 2-226.

Regarding the arrangement and length in the axial direction of the grooves 2-226, a short groove may be provided only at an upper end 2-241 of the outer peripheral part 2-210 as illustrated in FIG. 21A, it may be over a half 240 of the length in the axial direction of the outer peripheral part 2-210, or it may be over an entire length 242 of the length in the axial direction of the outer peripheral part 2-210 further. It can be selected depending on how much eddy current the eddy current 228 generated in the peripheral direction of the outer peripheral part 2-210 generates at the conductive film which is the measurement object.

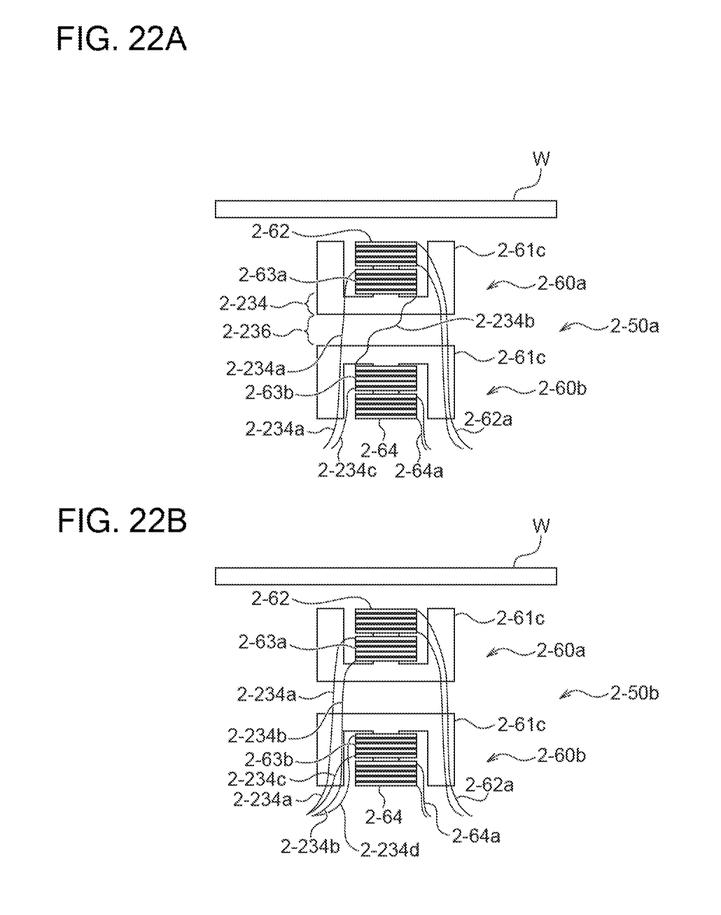

FIGS. 22A and 22B illustrate another embodiment of the eddy current sensor. In FIGS. 22A and 22B, an eddy current sensor 2-50a includes a first pot core 2-60a, and a second pot core 2-60b arranged in the vicinity of the first pot core 2-60a. The first pot core 2-60a and the second pot core 2-60b include the bottom surface part 2-61a, the magnetic core part 2-61b provided on the center of the bottom surface part 2-61a, and the peripheral wall part 2-61c provided around the magnetic core part 2-61b.

The eddy current sensor 2-50a includes a first excitation coil 2-63a that is arranged at the magnetic core part 2-61b of the first pot core 2-60a and forms the eddy current at the conductive film W. The eddy current sensor 2-50a further includes the detection coil 2-63 that is arranged at the magnetic core part 2-61b of the first pot core 2-60a and detects the eddy current formed at the conductive film W, a second excitation coil 2-63b arranged at the magnetic core part 2-61b of the second pot core 2-60b, and the dummy coil 2-64 arranged at the magnetic core part 2-61b of the second pot core 2-60b. The axial direction of the magnetic core part 2-61b of the first pot core 2-60a and the axial direction of the magnetic core part 2-61b of the second pot core 2-60b coincide. The axial direction of the magnetic core part 2-61b of the first pot core 2-60a and the axial direction of the magnetic core part 2-61b of the second pot core 2-60b are orthogonal to the conductive film on the substrate W. The first pot core 2-60a and the second pot core 2-60b are arranged in the order of the first pot core 2-60a and the second pot core 2-60b from the position near the substrate W to the position far from the substrate W.

Further, while the first pot core 2-60a is opened toward the conductive film W, the second pot core 2-60b is opened toward the opposite of the conductive film W.

In the figure, differently from the embodiment in FIG. 18, two pot cores are used. In the case of the figure, the detection coil 2-63 and the dummy coil 2-64 are provided in the similar arrangement inside different pot cores. In the embodiment in FIG. 18, the detection coil 2-63 and the dummy coil 2-64 are provided inside one pot core. Therefore, a distance between the detection coil 2-63 and the bottom surface part 2-61a is longer than a distance between the dummy coil 2-64 and the bottom surface part 2-61a. That is, the detection coil 2-63 and the dummy coil 2-64 are not in the similar arrangement in relationship with the pot core. In the case of FIGS. 22A and 22B, since the detection coil 2-63 and the dummy coil 2-64 are provided in the similar arrangement inside the pot core, there is an advantage that the detection coil 2-63 and the dummy coil 2-64 indicate a similar characteristic in terms of an electric circuit.

In addition, in FIGS. 22A and 22B, differently from the embodiment in FIG. 18, the dummy coil 2-64 is far from the substrate W, so that it is not easily affected by the substrate W. Therefore, there is an advantage that the dummy coil 2-64 can accurately achieve the object of the dummy coil 2-64 to generate reference signals during measurement.

Further, in the case of FIG. 18, since the distance between the detection coil 2-63 and the bottom surface part 2-61a is longer than the distance between the dummy coil 2-64 and the bottom surface part 2-61a, the winding number of the conducting wire of the detection coil 2-63 needs to be increased to be larger than the winding number of the conducting wire of the dummy coil 2-64. This is because that the detection coil 2-63 is far from the magnetic core part 2-61b, so that it is not easily affected by the pot core compared to the dummy coil 2-64. As a result, the detection coil 2-63 and the dummy coil 2-64 are manufactured so as to have different characteristics. On the other hand, in FIGS. 22A and 22B, since the detection coil 2-63 and the dummy coil 2-64 are provided in the similar arrangement inside the pot core, they indicate the similar characteristic in terms of the electric circuit. Therefore, in the case of FIGS. 22A and 22B, the detection coil 2-63 and the dummy coil 2-64 can be the same ones. Thus, there is an advantage that the same ones can be manufactured for the first pot core 2-60a and the second pot core 2-60b.

A difference between FIG. 22A and FIG. 22B is a connection method of the first excitation coil 2-63a and the second excitation coil 2-63b. In FIG. 22A, the first excitation coil 2-63a and the second excitation coil 2-63b are connected in series. On the other hand, in FIG. 22B, the first excitation coil 2-63a and the second excitation coil 2-63b are not connected.

Specifically, in FIG. 22A, one terminal of the first excitation coil 2-63a and one terminal of the second excitation coil 2-63b are connected in series by a lead wire 2-234b. Thus, a lead wire 2-234a connected to the first excitation coil 2-63a and a lead wire 2-234c connected to the second excitation coil 2-63b are connected to an external signal source. On the other hand, in FIG. 22B, the two lead wires 2-234a and 234b connected to the first excitation coil 2-63a are connected to the external signal source, and two lead wires 2-234c and 234d connected to the second excitation coil 2-63b are connected to the external signal source. That is, in FIG. 22B, the first excitation coil 2-63a and the second excitation coil 2-63b are connected in parallel.

In the case of comparing the arrangement in FIGS. 22A and 22B with the arrangement in FIG. 18, there is also the following advantage. That is, in the case of FIGS. 22A and 22B, the distance between the detection coil 2-63 and the bottom surface part 2-61a is shorter than that in the case of FIG. 18. In the embodiment in FIG. 18, the dummy coil 2-64 is arranged between the detection coil 2-63 and the bottom surface part 2-61a. Therefore, the detection coil 2-63 in FIGS. 22A and 22B is easily affected by the bottom surface part 2-61a, that is, easily affected by the magnetic body. Thus, there is an advantage that the output of the detection coil 2-63 becomes larger in FIGS. 22A and 22B than in FIG. 18 when the winding number of the coil is the same.

Note that, regarding a distance 2-236 between the first pot core 2-60a and the second pot core 2-60b, it is preferable that the distance 2-236 is longer than a core bottom part thickness 2-234 in order to avoid magnetic field interference of the cores of each other. As a different method, a metal or the like may be inserted to the part of the distance 2-236 to perform shielding.

Note that, in the embodiments in FIG. 15 to FIGS. 22A and 22B, a frequency of electric signals applied to the excitation coil 2-62 is a frequency where a detection circuit does not oscillate which detects the eddy current formed at the conductive film, based on output of the eddy current sensor. By utilizing a frequency that is not oscillated, an operation of the circuit is stabilized.

In addition, a winding number of the conducting wires of the detection coil, the excitation coil and the dummy coil can be set to be a frequency not oscillated by the detection circuit which detects the eddy current formed at the conductive film based on the output of the eddy current sensor.

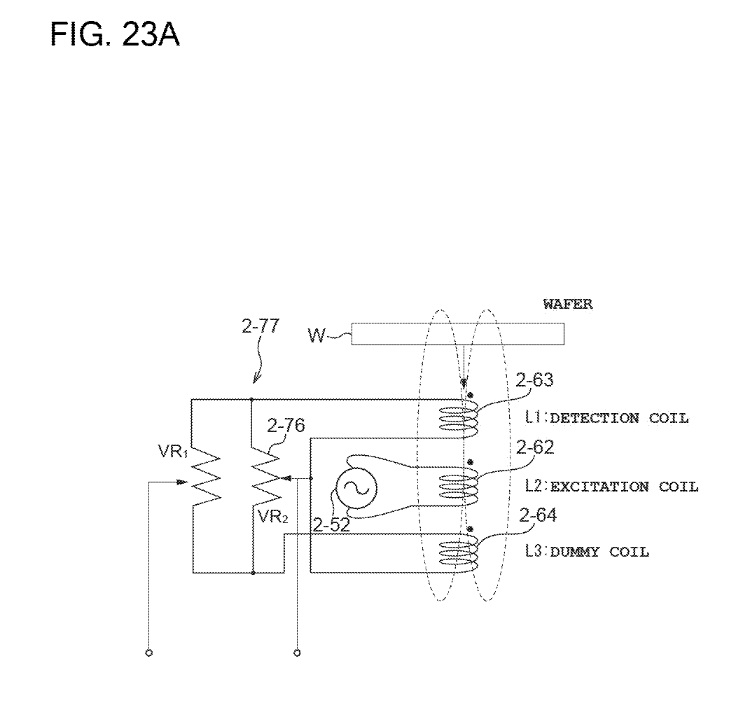

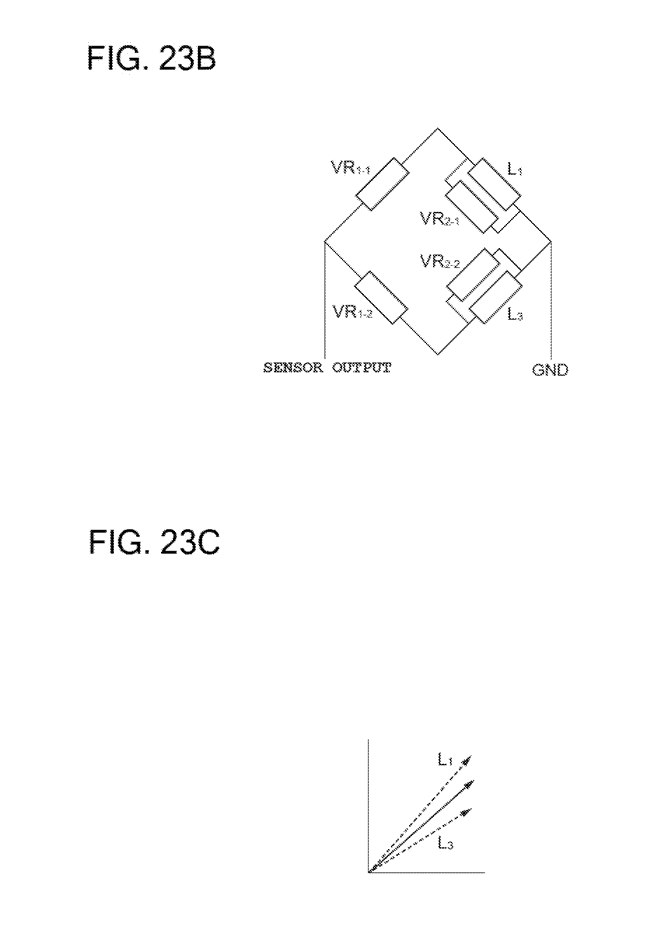

FIGS. 23A, 23B and 23C are schematic diagrams illustrating a connection example of the individual coils in the eddy current sensor. As illustrated in FIG. 23A, the detection coil 2-63 and the dummy coil 2-64 are connected in phases opposite to each other.

The detection coil 2-63 and the dummy coil 2-64 configure a serial circuit of the opposite phase as described above, and both ends thereof are connected to a resistor bridge circuit 77 including a variable resistor 76. The excitation coil 2-62 is connected to the AC signal source 2-52 and generates an alternating magnetic flux, thereby forming the eddy current at the metal film (or conductive film) mf arranged in the vicinity. By adjusting a resistance value of a variable resistor 2-76, an output voltage of the serial circuit formed of the coils 2-63 and 64 can be adjusted to be zero when the metal film (or conductive film) is not present. Signals of L₁ and L₃ are adjusted to be in phase by the variable resistors 2-76 (VR₁, VR₂) that enter in parallel each of the coils 2-63 and 64. That is, in an equivalent circuit in FIG. 23B, the variable resistors VR₁ (=VR₁₋₁+VR₁₋₂) and VR₂ (=VR₂₋₁+VR₂₋₂) are adjusted so as to satisfy

VR₁₋₁×(VR₂₋₂+jωL₃)=VR₁₋₂×(VR₂₋₁+jωL₁) (1).

Thus, as illustrated in FIG. 23C, the signals (indicated by dotted lines in the figure) of L₁ and L₃ before adjustment are turned to the signals (indicated by a solid line in the figure) of the same phase and same amplitude.

Then, when the metal film (or conductive film) is present in the vicinity of the detection coil 2-63, the magnetic flux generated by the eddy current formed in the metal film (or conductive film) interlinks with the detection coil 2-63 and the dummy coil 2-64, and since the detection coil 2-63 is arranged at the position nearer the metal film (or conductive film), balance of induction voltages generated in both coils 2-63 and 64 is lost, and thus an interlinkage magnetic flux formed by the eddy current of the metal film (or conductive film) can be detected. That is, by separating the serial circuit of the detection coil 2-63 and the dummy coil 2-64 from the excitation coil 2-62 connected to the AC signal source and adjusting the balance in the resistor bridge circuit, a zero point can be adjusted. Therefore, since the eddy current flowing to the metal film (or conductive film) can be detected from a zero state, detection sensitivity of the eddy current in the metal film (or conductive film) can be improved. Thus, the size of the eddy current formed at the metal film (or conductive film) can be detected in a wide dynamic range.

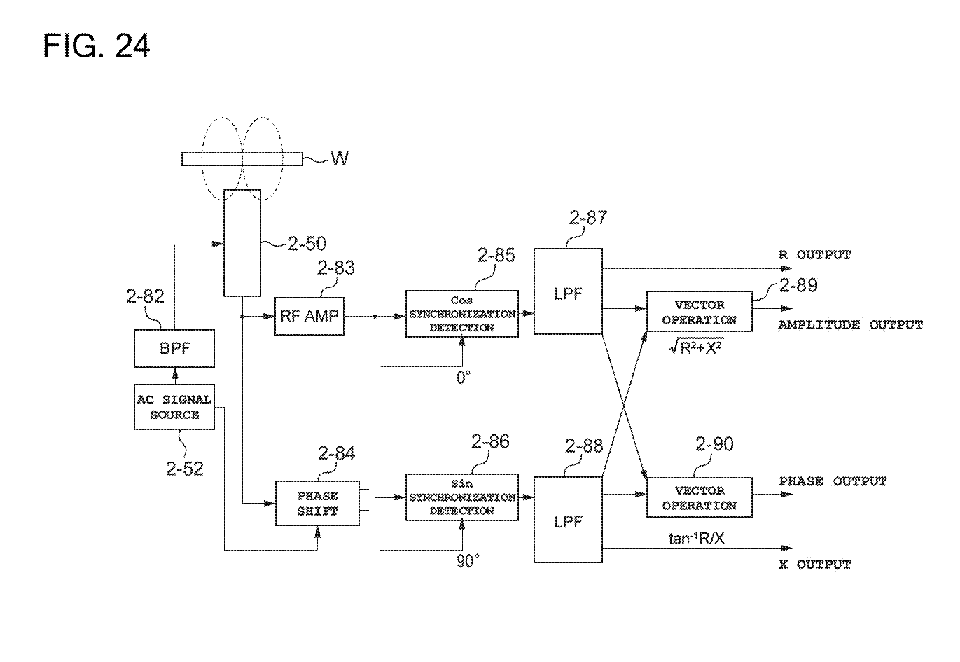

FIG. 24 is a block diagram illustrating a synchronization detection circuit of the eddy current sensor.

FIG. 24 illustrates a measurement circuit example of the impedance Z viewing the side of the eddy current sensor 2-50 from the side of the AC signal source 2-52. In a measurement circuit of the impedance Z illustrated in FIG. 24, a resistance component (R), a reactance component (X), amplitude output (Z) and phase output (tan⁻¹ R/X) accompanying the change of the film thickness can be taken out.

As described above, the signal source 2-52 that supplies AC signals to the eddy current sensor 2-50 arranged in the vicinity of the semiconductor wafer W where the metal film (or conductive film) mf of the detection object is formed is the oscillator of the fixed frequency formed of the crystal oscillator, and supplies the voltages of the fixed frequencies of 2 MHz and 8 MHz, for example. The AC voltage formed in the signal source 2-52 is supplied through a band-pass filter 2-82 to the eddy current sensor 2-50. Signals detected at a terminal of the eddy current sensor 2-50 are made to pass through a high frequency amplifier 2-83 and a phase shift circuit 2-84, and cos components and sin components of detection signals are taken out by a synchronization detection part formed of a cos synchronization detection circuit 2-85 and a sin synchronization detection circuit 2-86. Here, for oscillation signals formed in the signal source 2-52, two signals of in-phase components (0°) and orthogonal components (90°) of the signal source 2-52 are formed by the phase shift circuit 2-84 and are introduced into the cos synchronization detection circuit 2-85 and the sin synchronization detection circuit 2-86 respectively, and the above-described synchronization detection is carried out.

For synchronization detected signals, unneeded high frequency components higher than signal components are removed by low-pass filters 2-87 and 2-88, and resistance component (R) output which is cos synchronization detection output and reactance component (X) output which is sin synchronization detection output are taken out. In addition, by a vector operation circuit 2-89, amplitude output (R²+X²)^{1/2} is obtained from the resistance component (R) output and the reactance component (X) output. Also, by a vector operation circuit 2-90, phase output (tan⁻¹ R/X) is obtained similarly from the resistance component output and the reactance component output. Here, a measuring device main body is provided with various kinds of filters in order to eliminate noise components of sensor signals. To the various kinds of filters, cutoff frequencies corresponding to each of them are set, and by setting the cutoff frequency of the low-pass filter in the range of 0.1 to 10 Hz, for example, the noise components coexisting in the sensor signals during polishing are eliminated, and the metal film (or conductive film) of the measurement object can be highly accurately measured.

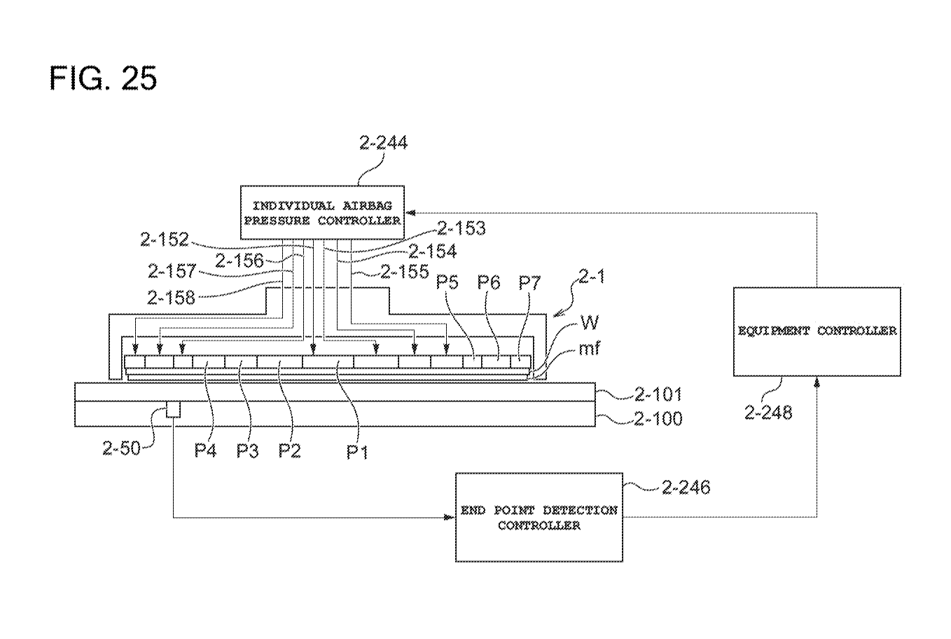

Note that, in the polishing device to which the individual embodiments described above are applied, as illustrated in FIG. 25, a plurality of pressure chambers (airbags) P1 to P7 can be provided in space inside the top ring 2-1, and an internal pressure of the pressure chambers P1 to P7 can be adjusted. That is, inside the space formed on an inner side of the top ring 2-1, the plurality of pressure chambers P1 to P7 are provided. The plurality of pressure chambers P1 to P7 include a circular pressure chamber P1 at the center and a plurality of annular pressure chambers P2 to P7 arranged concentrically on the outer side of the pressure chamber P1. The internal pressure of the individual pressure chambers P1 to P7 can be changed independently of each other by an individual airbag pressure controller 2-244. Thus, pressurizing force in individual areas of the substrate W at positions corresponding to the individual pressure chambers P1 to P7 can be independently adjusted.

In order to independently adjust the pressurizing force in the individual areas, it is needed to measure a wafer film thickness distribution by the eddy current sensor 2-50. As described below, the wafer film thickness distribution can be obtained from sensor output, a top ring rotation number and a table rotation number.

First, a track (scanning line) when the eddy current sensor 2-50 scans the surface of the semiconductor wafer will be described.

In one embodiment of the present invention, a rotation speed ratio of the top ring 2-1 and the polishing table 2-100 is adjusted so that the track drawn on the semiconductor wafer W by the eddy current sensor 2-50 within a predetermined period of time is roughly equally distributed over the entire surface of the semiconductor wafer W.

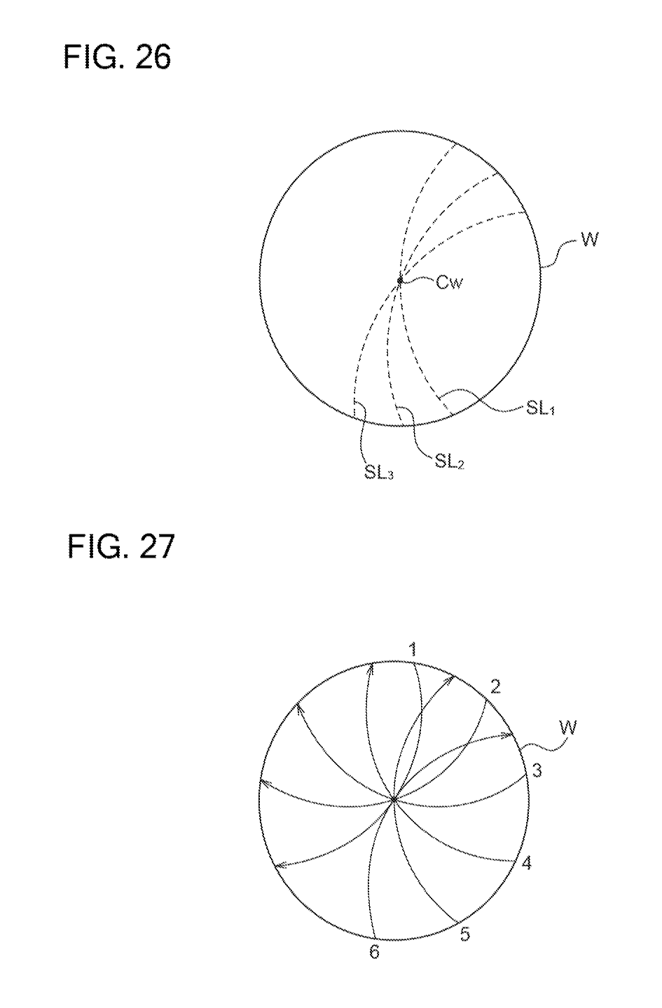

FIG. 26 is a schematic drawing illustrating the track that the eddy current sensor 2-50 performs a scan on the semiconductor wafer W. As illustrated in FIG. 26, the eddy current sensor 2-50 scans the surface (surface to be polished) of the semiconductor wafer W every time the polishing table 2-100 is rotated once, and when the polishing table 1-100 is rotated, the eddy current sensor 2-50 scans the surface to be polished of the semiconductor wafer W drawing the track roughly passing through the center Cw (the center of the top ring shaft 2-111) of the semiconductor wafer W. By making the rotation speed of the top ring 2-1 and the rotation speed of the polishing table 2-100 be different, the track of the eddy current sensor 2-50 on the surface of the semiconductor wafer W is changed like scanning lines SL₁, SL₂, SL₃, . . . accompanying the rotation of the polishing table 2-100 as illustrated in FIG. 26. Even in this case, as described above, since the eddy current sensor 2-50 is arranged at the position to pass through the center Cw of the semiconductor wafer W, the track drawn by the eddy current sensor 2-50 passes through the center Cw of the semiconductor wafer W every time.

FIG. 27 is a figure illustrating the track on the semiconductor wafer drawn by the eddy current sensor 2-50 within the predetermined period of time (5 seconds in this example) assuming that the rotation speed of the polishing table 2-100 is 70 min⁻¹ and the rotation speed of the top ring 2-1 is 77 min⁻¹. As illustrated in FIG. 27, under this condition, since the track of the eddy current sensor 2-50 rotates by 36 degrees every time the polishing table 2-100 is rotated once, the sensor track is rotated half around on the semiconductor wafer W every time the scan is performed for five times. When a curve of the sensor track is also taken into consideration, when the eddy current sensor 2-50 scans the semiconductor wafer W six times within the predetermined period of time, the eddy current sensor 2-50 roughly equally scans the entire surface of the semiconductor wafer W. For each track, the eddy current sensor 2-50 can perform measurement several hundreds of times. On the entire semiconductor wafer W, for example, the film thickness is measured at 1000 to 2000 measurement points to obtain the film thickness distribution.

While the above-described example illustrates the case that the rotation speed of the top ring 2-1 is faster than the rotation speed of the polishing table 2-100, also in the case that the rotation speed of the top ring 2-1 is slower than the rotation speed of the polishing table 2-100 (for example, the rotation speed of the polishing table 2-100 is 70 min⁻¹ and the rotation speed of the top ring 2-1 is 63 min⁻¹), the sensor track is just rotated in an opposite direction, and a point that the track drawn on the surface of the semiconductor wafer W by the eddy current sensor 2-50 within the predetermined period of time is distributed over the entire periphery of the surface of the semiconductor wafer W is the same as the above-described example.

A method of controlling the pressurizing force in the individual areas of the substrate W based on the obtained film thickness distribution will be described below. As illustrated in FIG. 25, the eddy current sensor 2-50 is connected to an end point detection controller 2-246, and the end point detection controller 2-246 is connected to an equipment controller 2-248. Output signals of the eddy current sensor 2-50 are sent to the end point detection controller 2-246. The end point detection controller 2-246 executes required processing (arithmetic processing/correction) to the output signals of the eddy current sensor 2-50 and generates monitoring signals (film thickness data corrected by the end point detection controller 2-246). The end point detection controller 2-246 operates the internal pressure of the individual pressure chambers P1 to P7 inside the top ring 2-1 based on the monitoring signals. That is, the end point detection controller 2-246 determines the force of pressurizing the substrate W by the top ring 2-1, and transmits the pressurizing force to the equipment controller 2-248. The equipment controller 2-248 issues a command to the individual airbag pressure controller 2-244 so as to change the pressurizing force to the substrate W of the top ring 2-1. The distribution of the film thickness of the substrate W detected by a film thickness sensor (eddy current sensor) 2-50 or signals corresponding to the film thickness is stored in the equipment controller 2-248. Then, according to the distribution of the film thickness of the substrate W or the signals corresponding to the film thickness transmitted from the end point detection controller 2-246, in the equipment controller 2-248, based on a polishing amount for a pressurizing condition stored in a database of the equipment controller 2-248, the pressurizing condition of the substrate W for which the distribution of the film thickness or the signals corresponding to the film thickness is detected is determined, and transmitted to the individual airbag pressure controller 2-244.

The pressurizing condition of the substrate W is determines as follows, for example. Based on information regarding a wafer area where the polishing amount is affected when the pressure of each airbag is changed, a film thickness average value of each wafer area is calculated. The wafer area to be affected is calculated from an experiment result or the like and inputted to the database of the equipment controller 2-248 beforehand. The pressure to an airbag part corresponding to the wafer area where the film is thin is lowered, the pressure to an airbag part corresponding to the wafer area where the film is thick is raised, and the airbag pressure is controlled so as to uniformize the film thickness of the individual areas. At the time, a polishing rate may be calculated from the past film thickness distribution result and may be turned to an indicator of the pressure to be controlled.

In addition, the distribution of the film thickness of the substrate W detected by the film thickness sensor or the signals corresponding to the film thickness may be transmitted to a high-order host computer (computer which is connected to and manages a plurality of semiconductor manufacturing devices) and stored in the host computer. Then, according to the distribution of the film thickness of the substrate W or the signals corresponding to the film thickness transmitted from the polishing device side, in the host computer, based on the polishing amount for the pressurizing condition stored in a database of the host computer, the pressurizing condition of the substrate W for which the distribution of the film thickness or the signals corresponding to the film thickness is detected is determined, and transmitted to the equipment controller 2-248 of the polishing device.

Next, a control flow of the pressurizing force of the individual areas of the substrate W will be described.

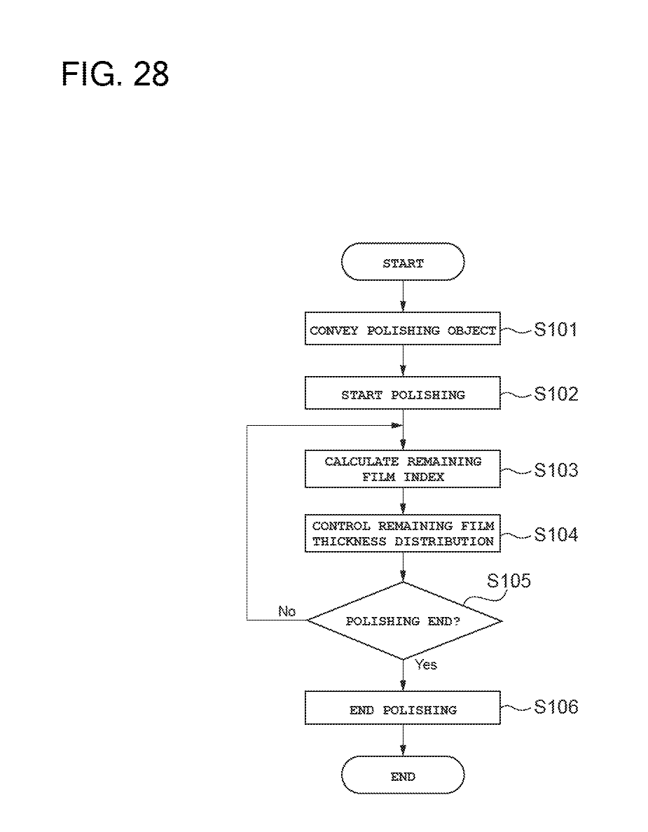

FIG. 28 is a flowchart illustrating one example of the operation of pressure control to be performed during polishing. First, the polishing device conveys the substrate W to a polishing position (step S101). Then, the polishing device starts polishing the substrate W (step S102).

Subsequently, the end point detection controller 2-246 calculates a remaining film index (film thickness data expressing a remaining film amount) for the individual areas of the polishing object while the substrate W is being polished (step S103). Then, the equipment controller 2-248 controls the distribution of the remaining film thickness based on the remaining film index (step S104).

Specifically, the equipment controller 2-248 independently controls the pressurizing force to be applied to the individual areas on a back surface of the substrate W (that is, the pressures inside the pressure chambers P1 to P7), based on the remaining film indexes calculated for the individual areas. Note that a polishing characteristic (polishing speed with respect to the pressure) sometimes becomes instable due to alteration of a film surface layer to be polished of the substrate W or the like in an initial period of polishing. In such a case, predetermined waiting time may be provided before the first control is performed after polishing is started.

Subsequently, an end point detector determines whether or not to end the polishing of the polishing object based on the remaining film index (step S105). When the end point detection controller 2-246 determines that the remaining film index has not reached a target value set beforehand (step S105, No), processing returns to step S103.

On the other hand, when the end point detection controller 2-246 determines that the remaining film index has reached the target value set beforehand (step S105, Yes), the equipment controller 2-248 ends the polishing of the polishing object (step S106). In steps S105 and 106, it is also possible to end the polishing by determining whether or not predetermined time has elapsed from the polishing start. According to the present embodiment, in the eddy current sensor, since a space resolution is improved, an effective range of eddy current sensor output spreads to the narrow area such as an edge, so that measurement points for each area of the substrate W increase, controllability of the polishing can be improved, and polishing flatness of the substrate can be improved.

As described above, the present invention includes the following forms.

According to a first form of a polishing device of the present invention, an eddy current sensor is arranged in the vicinity of a substrate where a conductive film is formed, the eddy current sensor includes a core part and a coil part, the core part includes a common part and four cantilever parts connected to an end of the common part, and a first cantilever part and a second cantilever part are arranged on an opposite side of a third cantilever part and a fourth cantilever part with respect to the common part. The first cantilever part and the third cantilever part are arranged at one end of the common part, and the second cantilever part and the fourth cantilever part are arranged at the other end of the common part. The coil part includes: an excitation coil that is arranged in the common part and is capable of forming an eddy current at the conductive film; a detection coil that is arranged in at least one of the first cantilever part and the second cantilever part, and is capable of detecting the eddy current formed at the conductive film; and a dummy coil that is arranged in at least one of the third cantilever part and the fourth cantilever part. Ends of the first cantilever part and the second cantilever part far from parts where the first cantilever part and the second cantilever part are connected with the common part are close and adjacent to each other, and ends of the third cantilever part and the fourth cantilever part far from parts where the third cantilever part and the fourth cantilever part are connected with the common part are close and adjacent to each other.

According to this form, since the core part in which the ends of the first cantilever part and the second cantilever part are close and adjacent to each other and the ends of the third cantilever part and the fourth cantilever part are close and adjacent to each other is used, the magnetic flux generated by the excitation coil leaks from the core part to the outside only at a gap between a distal end of the first cantilever part and a distal end of the second cantilever part, and a gap between a distal end of the third cantilever part and a distal end of the fourth cantilever part, so that a small spot diameter of the magnetic flux can be formed outside the eddy current sensor. That is, the magnetic flux can be converged narrowly by the shape of the core part, and the spatial resolution of the eddy current sensor can be improved. Since the film thickness of the range narrower than the conventional case can be measured, accuracy of polishing end point detection can be improved at the edge or the like of the semiconductor wafer.

It is preferable that the coil part includes a first detection coil that is arranged at the first cantilever part and detects the eddy current formed at the conductive film, and a first dummy coil arranged at the third cantilever part. Or, it is preferable that the coil part includes the first detection coil that is arranged at the first cantilever part and detects the eddy current formed at the conductive film, a first dummy coil arranged at the third cantilever part, a second detection coil that is arranged at the second cantilever part and detects the eddy current formed at the conductive film, and a second dummy coil arranged at the fourth cantilever part.

According to a second form of the present invention, the ends of the first cantilever part and the second cantilever part are close and adjacent to each other so that the core part is a tapered shape in a direction away from parts where the first cantilever part and the second cantilever part are connected with the common part, and the ends of the third cantilever part and the fourth cantilever part are close and adjacent to each other so that the core part is a tapered shape in a direction away from parts where the third cantilever part and the fourth cantilever part are connected with the common part respectively.

According to a third form of the present invention, the four cantilever parts have two orthogonal center lines, the first cantilever part and the second cantilever part are symmetrical with respect to one of the center lines, the third cantilever part and the fourth cantilever part are symmetrical with respect to the one of the center lines, the first cantilever part and the third cantilever part are symmetrical with respect to the other center line, and the second cantilever part and the fourth cantilever part are symmetrical with respect to the other center line.

According to a fourth form of the present invention, a metallic outer peripheral part arranged outside the core part and outside the coil part is provided. By surrounding the periphery of the outside of the core part and the outside of the coil part by the metal, the magnetic field that spreads out is shielded and the spatial resolution of the sensor can be improved. An insulating material may be arranged outside the core part and outside the coil part and the metal may be arranged so as to surround the insulating material. In addition, the outer peripheral part may be grounded. In this case, a magnetic shielding effect is stabilized and increased.

According to a fifth form of the present invention, the outer peripheral part includes at least one groove extending in a longitudinal direction of the eddy current sensor. In this way, by making cuts (grooves) at the peripheral part, the generation of the eddy current in the peripheral direction at the outer peripheral part can be prevented.

According to a sixth form of the present invention, conducting wires used in the detection coil and the excitation coil are copper, manganin wires or nichrome wires. By using the manganin wires or the nichrome wires, temperature change of electric resistance or the like is reduced and temperature characteristics are improved.

According to a seventh form of the present invention, a frequency of electric signals applied to the excitation coil is a frequency where a detection circuit does not oscillate which detects an eddy current formed at the conductive film, based on output of the eddy current sensor.

According to an eighth form of the present invention, a winding number of conducting wires of the detection coil, the excitation coil and the dummy coil is set so as to cause a frequency where a detection circuit does not oscillate which detects an eddy current formed at the conductive film, based on output of the eddy current sensor.

According to a ninth form of the present invention, an eddy current sensor is arranged in the vicinity of a substrate where a conductive film is formed, and the eddy current sensor includes a sensor part and a dummy part arranged in a vicinity of the sensor part. The sensor part includes a sensor core part and a sensor coil part, the sensor core part includes a sensor common part and a first cantilever part and a second cantilever part connected to the sensor common part, and the first cantilever part and the second cantilever part are arranged facing each other. The dummy part includes a dummy core part and a dummy coil part, the dummy core part includes a dummy common part and a fourth cantilever part and a third cantilever part connected to the dummy common part, and the fourth cantilever part and the third cantilever part are arranged facing each other. The sensor coil part includes a sensor excitation coil that is arranged in the sensor common part and is capable of forming an eddy current at the conductive film, and a detection coil that is arranged in at least one of the first cantilever part and the second cantilever part, and is capable of detecting the eddy current formed at the conductive film. The dummy coil part includes a dummy excitation coil that is arranged in the dummy common part, and a dummy coil that is arranged in at least one of the third cantilever part and the fourth cantilever part. Ends of the first cantilever part and the second cantilever part far from parts where the first cantilever part and the second cantilever part are connected with the sensor common part are close and adjacent to each other, ends of the third cantilever part and the fourth cantilever part far from parts where the third cantilever part and the fourth cantilever part are connected with the dummy common part are close and adjacent to each other, and the sensor part and the dummy part are arranged in an order of the sensor part and the dummy part from a position near the substrate to a position far from the substrate.

Note that, in the case of using the dummy coil, since measurement is performed by a bridge circuit, a capacitor is not added unlike a measurement system of a resonance type, so that the measurement can be performed with a high frequency. For example, 30 MHz can be adopted. It is advantageous when measuring a metallic film of high sheet resistance. It is because that the metal of higher resistance needs a higher frequency when detecting the change of the thickness of a thin film.

According to a tenth form of the present invention, a polishing device is provided including: a polishing table to which a polishing pad for polishing a polishing object including the conductive film is stuck; a drive part that rotationally drives the polishing table; a holding part that holds the polishing object and pressurizes the polishing object to the polishing pad; the eddy current sensor according to any one of the first form to the ninth form that is arranged inside the polishing table and detects the eddy current formed at the conductive film accompanying rotation of the polishing table along a polishing surface of the polishing object; and an end point detection controller that calculates film thickness data of the polishing object from the detected eddy current.

According to an eleventh form of the present invention, the polishing device is provided including an equipment controller that independently controls pressurizing force of a plurality of areas of the polishing object, based on the film thickness data calculated by the end point detection controller.

According to a twelfth form of the polishing device of the present invention, an eddy current sensor is arranged in the vicinity of a substrate where a conductive film is formed, and the eddy current sensor includes: a pot core which is a magnetic body including a bottom surface part, a magnetic core part provided on a center of the bottom surface part, and a peripheral wall part provided around the bottom surface part; an excitation coil that is arranged at the magnetic core part and forms an eddy current at the conductive film; and a detection coil that is arranged at the magnetic core part, and detects the eddy current formed at the conductive film. Relative permittivity of the magnetic body is 5 to 15, relative permeability is 1 to 300, an outside dimension of the magnetic core part is 50 mm or smaller, and electric signals of a frequency of 2 to 30 MHz are applied to the excitation coil. Here, the outside dimension of the magnetic core part is the maximum dimension of a cross section of the core part vertical to a magnetic field applied to the magnetic core part by the excitation coil.

According to the form above, since the pot core is used, the magnetic flux generated by the excitation coil is limited between the distal end of the magnetic core part and the distal end of the peripheral wall part, and the small spot diameter of the magnetic flux can be formed. In addition, in the case that the relative permittivity of the magnetic body is 5 to 15, the relative permeability is 1 to 300, the outside dimension of the magnetic core part is 50 mm or smaller, and the electric signals of a frequency of 2 to 30 MHz are applied to the excitation coil, since the dimensional resonance of the electromagnetic waves is not generated, the magnetic flux becomes strong. Therefore, the strong magnetic flux is generated while converging the magnetic flux narrow by the shape of the pot core, and the spatial resolution of the sensor can be improved. Since the film thickness of the narrower range can be measured with the strong magnetic flux, measurement can be performed to the vicinity of the edge of the wafer. As the magnetic body, for example, it is preferable to use the Ni—Zn-based ferrite having the above-described characteristic.

Here, a condition of not causing the dimensional resonance will be described. The dimensional resonance appears when the maximum dimension of the cross section of the core vertical to the magnetic field is an integral multiple of about ½ of a wavelength λ of the electromagnetic waves. There is the following relationship between a characteristic of the material and the wavelength that causes the dimensional resonance.

λ=C/f×√(μₛ×εᵣ)

Here, C: Vacuum electromagnetic wave speed (3.0×10⁸ m/s)

μₛ: Relative permeability

εᵣ: Relative permittivity

f: Frequency of magnetic field (electromagnetic waves) to be applied

In order to prevent the dimensional resonance, the minimum dimension that causes the dimensional resonance is determined from the material to be used and the frequency, and the dimension of the core is made smaller than the minimum dimension that causes the dimensional resonance. In the case of one embodiment of the present invention, it is recognized that the minimum dimension that causes the dimensional resonance is about 7.5 cm from the above equation. Therefore, since the outside dimension of the magnetic core part is 50 mm or smaller, the dimensional resonance is not generated in one embodiment of the present invention.

Note that the frequency of 2 MHz to 30 MHz is the frequency that is needed for a purpose of detecting the change of the thickness of a metallic thin film. As the film becomes thinner, and as the resistance value of the thin film becomes larger, it is needed to apply the signals of the higher frequency in order to detect the change of the thickness of the thin film. It is needed in the polishing device to apply the high frequency of 2 MHz to 30 MHz to the excitation coil. In addition, numerical values that the relative permittivity is 5 to 15 and the relative permeability is 1 to 300 can be achieved by the Ni—Zn-based ferrite.

In addition, the relative permittivity is a ratio ε/ε₀=εᵣ of the permittivity ε of a material and vacuum permittivity ε₀. The measurement is in accordance with JIS2138 “Electrical insulating materials—Methods for the determination of the relative permittivity and dielectric dissipation factor”. The relative permeability is a ratio μₛ=μ/μ₀ of the permeability μ of the material and vacuum permeability μ₀. The measurement is in accordance with JISC2560-2 “Cores made of ferrite: Measuring methods”.

In the case that the material of the magnetic body is the Ni—Zn-based ferrite, since the values of both permeability and permittivity are low for the Ni—Zn-based ferrite compared to Mn—Zn-based ferrite, the dimensional resonance of the electromagnetic waves is not generated and thus the magnetic flux becomes strong. As a result, while the magnetic flux is converged narrowly by the shape of the pot core, the strong magnetic flux is generated and the spatial resolution of the sensor can be improved.

According to a thirteenth form of the present invention, the eddy current sensor includes a dummy coil that is arranged at the magnetic core part and detects the eddy current formed at the conductive film.

At the time, it is preferable that the detection coil, the excitation coil and the dummy coil are arranged at different positions in the axial direction of the magnetic core part, and are arranged in the order of the detection coil, the excitation coil and the dummy coil from the position near the conductive film on the substrate to the position far from the conductive film in the axial direction of the magnetic core part.

According to a fourteenth form of the present invention, an eddy current sensor is arranged in the vicinity of a substrate where a conductive film is formed, the eddy current sensor includes a first pot core and a second pot core arranged in the vicinity of the first pot core, and the first pot core and the second pot core each include a bottom surface part, a magnetic core part provided on a center of the bottom surface part, and a peripheral wall part provided around the bottom surface part. The eddy current sensor includes: a first excitation coil that is arranged in the magnetic core part of the first pot core and forms an eddy current at the conductive film; a detection coil that is arranged at the magnetic core part of the first pot core, and detects the eddy current formed at the conductive film; a second excitation coil that is arranged at the magnetic core part of the second pot core; and a dummy coil that is arranged at the magnetic core part of the second pot core. An axial direction of the magnetic core part of the first pot core and an axial direction of the magnetic core part of the second pot core coincide, and the first pot core and the second pot core are arranged in the order of the first pot core and the second pot core from a position near the substrate to a position far from the substrate.

According to a fifteenth form of the present invention, the relative permittivity of the magnetic bodies is 5 to 15, the relative permeability of the magnetic bodies is 1 to 300, the outside dimension of the magnetic core parts is 50 mm or smaller, and the electric signals of a frequency 2 to 30 MHz are applied to the first and second excitation coils.

According to a sixteenth form of the present invention, the metallic outer peripheral part arranged outside the peripheral wall part is provided. By surrounding the periphery of the peripheral wall part by the metal, the magnetic field that spreads out is shielded and the spatial resolution of the sensor can be improved. The metal may be directly plated on the peripheral wall part, or an insulating material may be arranged around the peripheral wall part and the metal may be arranged so as to surround the insulating material. In addition, the outer peripheral part may be grounded. In this case, a magnetic shielding effect is stabilized and increased.

According to a seventeenth form of the present invention, the outer peripheral part includes at least one groove extending in the axial direction of the magnetic core part. In this way, by making cuts (grooves) at the outer peripheral part, the generation of the eddy current in the peripheral direction at the outer peripheral part can be prevented.

According to an eighteenth form of the present invention, conducting wires used in the detection coil and the excitation coil are copper, manganin wires or nichrome wires. By using the manganin wires or the nichrome wires, temperature change of electric resistance or the like is reduced and temperature characteristics are improved.

According to a nineteenth form of the present invention, a frequency of electric signals applied to the excitation coil is a frequency where a detection circuit does not oscillate which detects an eddy current formed at the conductive film, based on output of the eddy current sensor.

According to a twentieth form of the present invention, a winding number of conducting wires of the detection coil, the excitation coil and the dummy coil is set so as to cause a frequency where a detection circuit does not oscillate which detects an eddy current formed at the conductive film, based on output of the eddy current sensor.

Note that, in the case of using the dummy coil, since measurement is performed by a bridge circuit, a capacitor is not added unlike a measurement system of a resonance type, so that the measurement can be performed with a high frequency. For example, 30 MHz can be adopted. It is advantageous when measuring a metallic film of high sheet resistance. It is because that the metal of higher resistance needs a higher frequency when detecting the change of the thickness of a thin film.

According to a twenty first form of the present invention, a polishing device is provided including: a polishing table to which a polishing pad for polishing a polishing object including a conductive film is stuck; a drive part that rotationally drives the polishing table; a holding part that holds the polishing object and pressurizes the polishing object to the polishing pad; the eddy current sensor according to any one of the twelfth form to the twentieth form that is arranged inside the polishing table and detects the eddy current formed at the conductive film accompanying rotation of the polishing table along a polishing surface of the polishing object; and an end point detection controller that calculates film thickness data of the polishing object from the detected eddy current.

According to a twenty second form of the present invention, the polishing device is provided including an equipment controller that independently controls pressurizing force of a plurality of areas of the polishing object, based on the film thickness data calculated by the end point detection controller.

Although the embodiments of the present invention have been described above, the described embodiments are for the purpose of facilitating the understanding of the present invention and are not intended to limit the present invention. The present invention may be modified and improved without departing from the spirit thereof, and the invention naturally includes equivalents thereof. In addition, the elements described in the claims and the specification can be arbitrarily combined or omitted within a range in which the above-mentioned problems are at least partially solved, or within a range in which at least a part of the advantages is achieved.

This application claims priority under the Paris Convention to Japanese Patent Application No. 2015-172007 filed on Sep. 1, 2015 and Japanese Patent Application No. 2015-183003 filed on Sep. 16, 2015. The entire disclosure of Japanese Patent Laid-Open No. 2012-135865, Japanese Patent Laid-Open No. 2013-58762, and Japanese Patent Laid-Open No. 2009-204342 including specification, claims, drawings and summary is incorporated herein by reference in its entirety.

What is claimed is:

1. An eddy current sensor arranged in a vicinity of a substrate where a conductive film is formed, the eddy current sensor comprising:
a core part and a coil part,
wherein the core part includes a common part and four cantilever parts connected to an end of the common part, a first cantilever part and a second cantilever part are arranged on an opposite side of a third cantilever part and a fourth cantilever part with respect to the common part,
wherein the first cantilever part and the third cantilever part are arranged at one end of the common part, and the second cantilever part and the fourth cantilever part are arranged at the other end of the common part,
wherein the coil part includes:
an excitation coil that is arranged in the common part and is capable of forming an eddy current at the conductive film;
a detection coil that is arranged in at least one of the first cantilever part and the second cantilever part, and is capable of detecting the eddy current formed at the conductive film; and
a dummy coil that is arranged in at least one of the third cantilever part and the fourth cantilever part,
wherein ends of the first cantilever part and the second cantilever part far from parts where the first cantilever part and the second cantilever part are connected with the common part are close and adjacent to each other, and
wherein ends of the third cantilever part and the fourth cantilever part far from parts where the third cantilever part and the fourth cantilever part are connected with the common part are close and adjacent to each other.

2. The eddy current sensor according to claim 1,
wherein ends of the first cantilever part and the second cantilever part are close and adjacent to each other so that the core part is a tapered shape in a direction away from parts where the first cantilever part and the second cantilever part are connected with the common part, and
wherein ends of the third cantilever part and the fourth cantilever part are close and adjacent to each other so that the core part is a tapered shape in a direction away from parts where the third cantilever part and the fourth cantilever part are connected with the common part.

3. The eddy current sensor according to claim 1,
wherein the four cantilever parts have two orthogonal center lines,
wherein the first cantilever part and the second cantilever part are symmetrical with respect to one of the center lines,
wherein the third cantilever part and the fourth cantilever part are symmetrical with respect to the one of the center lines,
wherein the first cantilever part and the third cantilever part are symmetrical with respect to the other center line, and
wherein the second cantilever part and the fourth cantilever part are symmetrical with respect to the other center line.

4. The eddy current sensor according to claim 1, comprising an outer peripheral part made of a magnetic body or a metal and arranged outside the core part and outside the coil part.

5. The eddy current sensor according to claim 4, wherein the outer peripheral part includes at least one groove extending in a longitudinal direction of the eddy current sensor.

6. The eddy current sensor according to any one of claim 1, wherein conducting wires used in the detection coil and the excitation coil are copper, manganin wires or nichrome wires.

7. The eddy current sensor according to claim 1, wherein a frequency of electric signals applied to the excitation coil is a frequency where a detection circuit does not oscillate which detects an eddy current formed at the conductive film, based on output of the eddy current sensor.

8. The eddy current sensor according to claim 1, wherein a winding number of conducting wires of the detection coil and the excitation coil is set so as to cause a frequency where a detection circuit does not oscillate which detects an eddy current formed at the conductive film, based on output of the eddy current sensor.

9. An eddy current sensor arranged in a vicinity of a substrate where a conductive film is formed, the eddy current sensor comprising
a sensor part and a dummy part arranged in a vicinity of the sensor part,
wherein the sensor part includes a sensor core part and a sensor coil part,
wherein the sensor core part includes a sensor common part and a first cantilever part and a second cantilever part connected to the sensor common part,
wherein the first cantilever part and the second cantilever part are arranged facing each other,
wherein the dummy part includes a dummy core part and a dummy coil part,
wherein the dummy core part includes a dummy common part and a third cantilever part and a fourth cantilever part connected to the dummy common part,
wherein the third cantilever part and the fourth cantilever part are arranged facing each other,
wherein the sensor coil part includes:
a sensor excitation coil that is arranged in the sensor common part and is capable of forming an eddy current at the conductive film; and a detection coil that is arranged in at least one of the first cantilever part and the second cantilever part, and is capable of detecting the eddy current formed at the conductive film,
wherein the dummy coil part includes:
a dummy excitation coil that is arranged in the dummy common part; and a dummy coil that is arranged in at least one of the third cantilever part and the fourth cantilever part,
wherein ends of the first cantilever part and the second cantilever part far from parts where the first cantilever part and the second cantilever part are connected with the sensor common part are close and adjacent to each other,
wherein ends of the third cantilever part and the fourth cantilever part far from parts where the third cantilever part and the fourth cantilever part are connected with the dummy common part are close and adjacent to each other, and
wherein the sensor part and the dummy part are arranged in an order of the sensor part and the dummy part from a position near the substrate to a position far from the substrate.

10. A polishing device comprising:
a polishing table to which a polishing pad for polishing a polishing object including the conductive film is stuck;
a drive part that rotationally drives the polishing table;
a holding part that holds the polishing object and pressurizes the polishing object to the polishing pad;
the eddy current sensor according to claim 1 that is arranged inside the polishing table and detects the eddy current formed at the conductive film accompanying rotation of the polishing table along a polishing surface of the polishing object; and
an end point detection controller that calculates film thickness data of the polishing object from the detected eddy current.

11. The polishing device according to claim 10, comprising an equipment controller that independently controls pressurizing force of a plurality of areas of the polishing object, based on the film thickness data calculated by the end point detection controller.

12. An eddy current sensor arranged in a vicinity of a substrate where a conductive film is formed, the eddy current sensor comprising:
a pot core which is a magnetic body including a bottom surface part, a magnetic core part provided on a center of the bottom surface part, and a peripheral wall part provided around the bottom surface part;
an excitation coil that is arranged at the magnetic core part and forms an eddy current at the conductive film; and
a detection coil that is arranged at the magnetic core part, and detects the eddy current formed at the conductive film,
wherein relative permittivity of the magnetic body is 5 to 15, and relative permeability is 1 to 300,
wherein an outside dimension of the magnetic core part is 50 mm or smaller, and
wherein electric signals of a frequency of 2 to 30 MHz are applied to the excitation coil.

13. The eddy current sensor according to claim 12, comprising a dummy coil that is arranged at the magnetic core part and detects the eddy current formed at the conductive film.

14. An eddy current sensor arranged in a vicinity of a substrate where a conductive film is formed, the eddy current sensor comprising:
a first pot core which is a magnetic body; and a second pot core which is a magnetic body arranged in the vicinity of the first pot core,
wherein the first pot core and the second pot core each include a bottom surface part, a magnetic core part provided on a center of the bottom surface part, and a peripheral wall part provided around the bottom surface part,
wherein the eddy current sensor includes:
a first excitation coil that is arranged in the magnetic core part of the first pot core and forms an eddy current at the conductive film;
a detection coil that is arranged at the magnetic core part of the first pot core, and detects the eddy current formed at the conductive film;
a second excitation coil that is arranged at the magnetic core part of the second pot core; and
a dummy coil that is arranged at the magnetic core part of the second pot core,
wherein an axial direction of the magnetic core part of the first pot core and an axial direction of the magnetic core part of the second pot core coincide, and
wherein the first pot core and the second pot core are arranged in an order of the first pot core and the second pot core from a position near the substrate to a position far from the substrate.

15. The eddy current sensor according to claim 14,
wherein relative permittivity of the magnetic bodies is 5 to 15, and relative permeability of the magnetic bodies is 1 to 300,
wherein an outside dimension of the magnetic core parts is 50 mm or smaller, and
wherein electric signals of a frequency of 2 to 30 MHz are applied to the first and second excitation coils.

16. The eddy current sensor according to claim 12, comprising a metallic outer peripheral part arranged at the outside of the peripheral wall part.

17. The eddy current sensor according to claim 16, wherein the outer peripheral part includes at least one groove extending in the axial direction of the magnetic core part.

18. The eddy current sensor according to claim 12, wherein conducting wires used in the detection coil and the excitation coil are copper, manganin wires or nichrome wires.

19. The eddy current sensor according to claim 12, wherein a frequency of electric signals applied to the excitation coil is a frequency where a detection circuit does not oscillate which detects an eddy current formed at the conductive film, based on output of the eddy current sensor.

20. The eddy current sensor according to claim 12, wherein a winding number of conducting wires of the detection coil and the excitation coil is set so as to cause a frequency where a detection circuit does not oscillate which detects an eddy current formed at the conductive film, based on output of the eddy current sensor.

21. A polishing device comprising:
a polishing table to which a polishing pad for polishing a polishing object including the conductive film is stuck;
a drive part that rotationally drives the polishing table;
a holding part that holds the polishing object and pressurizes the polishing object to the polishing pad;
the eddy current sensor according to claim 12 that is arranged inside the polishing table and detects the eddy current formed at the conductive film accompanying rotation of the polishing table along a polishing surface of the polishing object; and
an end point detection controller that calculates film thickness data of the polishing object from the detected eddy current.

22. The polishing device according to claim 21, comprising
an equipment controller that independently controls pressurizing force of a plurality of areas of the polishing object, based on the film thickness data calculated by the end point detection controller.
